(19) United States
(12) Patent Application Publication
(10) Pub. No.: US 2025/0142877 A1
(43) Pub. Date: May 1, 2025

(54) GATE TRENCH POWER SEMICONDUCTOR DEVICES HAVING TRENCH SHIELDING REGIONS AND SUPPORT SHIELDS THAT EXTEND TO DIFFERENT DEPTHS

(71) Applicant: Wolfspeed, Inc., Durham, NC (US)

(72) Inventors: Woongsun Kim, Cary, NC (US); Naeem Islam, Morrisville, NC (US); Madankumar Sampath, Morrisville, NC (US); Sei-Hyung Ryu, Cary, NC (US)

(21) Appl. No.: 18/493,838

(22) Filed: Oct. 25, 2023

(51) Int. Cl. H01L 29/78; H01L 29/16; H01L 29/423

(52) U.S. Cl. CPC H10D 30/668; H10D 30/615; H10D 62/8325; H10D 64/514

(57) ABSTRACT

A semiconductor device comprises a silicon carbide based semiconductor layer structure that comprises a drift region having a first conductivity type and an implanted region having a second conductivity type on the drift region. First and second gate trench sections extend into the semiconductor layer structure. A first maximum depth into the semiconductor layer structure of a first portion of the implanted region that is between the first gate trench section and the second gate trench section is different than a second maximum depth into the semiconductor layer structure of a second portion of the implanted region that extends downwardly underneath the first gate trench section.

### FIELD OF THE INVENTION

The present invention relates to power semiconductor devices and, more particularly, to power semiconductor devices having gate trenches and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure that are separated by a channel region. A gate electrode (which may act as the gate terminal or be electrically connected to the gate terminal) is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a planar gate electrode design in which the gate electrode of the transistor is formed on top of the semiconductor layer structure or, alternatively, may have at least a portion of the gate electrode in a gate trench within the semiconductor layer structure, which are typically referred to as gate trench MOSFETs. With the planar gate electrode design, the channel region of each unit cell transistor is horizontally disposed underneath the gate electrode. In contrast, in the gate trench MOSFET design, the channels are typically vertically disposed adjacent sidewalls of the gate electrodes. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

Pursuant to some embodiments of the present invention, semiconductor devices are provided that comprise a silicon carbide based semiconductor layer structure that comprises a drift region having a first conductivity type and an implanted region having a second conductivity type on the drift region, a first gate trench section extending in the semiconductor layer structure, and a second gate trench section extending in the semiconductor layer structure. A first maximum depth into the semiconductor layer structure of a first portion of the implanted region that is between the first gate trench section and the second gate trench section is different than a second maximum depth into the semiconductor layer structure of a second portion of the implanted region that extends downwardly underneath the first gate trench section.

In some embodiments, the first maximum depth is greater than the second maximum depth.

In some embodiments, the implanted region comprises a first trench shielding region that is below the first gate trench section, a second trench shielding region that is below the second gate trench section and a support shield that is at least partially in between the first gate trench section and the second gate trench section.

In some embodiments, the semiconductor layer structure further comprises a well region having the second conductivity type on the drift region, an upper portion of the drift region comprises a JFET region that has a higher concentration of first conductivity type dopants than a lower portion of the drift region, and the support shield extends downwardly through the JFET region into the lower portion of the drift region.

In some embodiments, the first trench shielding region and the second trench shielding region do not extend through the JFET region into the lower portion of the drift region.

In some embodiments, a width of the first trench shielding region is less than a width of the support shield and a width of the second trench shielding region is less than the width of the support shield. In other embodiments, a width of the first trench shielding region is greater than a width of the support shield and a width of the second trench shielding region is greater than the width of the support shield.

In some embodiments, a width of the first trench shielding region is less than a width of the first gate trench and a width of the second trench shielding region is less than a width of the second gate trench.

In some embodiments, the semiconductor device further comprises a first gate dielectric layer in the first gate trench section and a second gate dielectric layer in the second gate trench section. A lateral thickness of a first portion of the first gate dielectric layer that is on a first sidewall of the first gate trench section that faces the second gate trench section is greater than a lateral thickness of a second portion of the first gate dielectric layer that is on a second sidewall of the first gate trench section. Additionally, a lateral thickness of a first portion of the second gate dielectric layer that is on a first sidewall of the second gate trench section that faces the first gate trench section is greater than a lateral thickness of a second portion of the second gate dielectric layer that is on a second sidewall of the second gate trench section.

In some embodiments, a thickness of a bottom portion of the first gate dielectric layer is greater than a thickness of the first portion of the first gate dielectric layer, and a thickness of a bottom portion of the second gate dielectric layer is greater than a thickness of the first portion of the second gate dielectric layer.

In some embodiments, the first gate trench section is part of a first gate trench, the second gate trench section is part of a second gate trench, where the second gate trench is spaced apart from the first gate trench and extends in parallel to the first gate trench.

In some embodiments, the semiconductor device further comprises a third gate trench extending into the semiconductor layer structure, where the first and third gate trenches are the closest gate trenches to the second gate trench. The support shield may be a first support shield and the semiconductor layer structure may further comprise a second support shield having the second conductivity type in between the second gate trench and the third gate trench. In some embodiments, a minimum distance between the second gate trench and the second support shield is greater than a minimum distance between the second gate trench and the first support shield.

In some embodiments, the first gate trench section and the second gate trench section are both part of a first gate trench.

In some embodiments, the first gate trench has a closed ring shape when viewed from above.

In some embodiments, the first maximum depth is less than the second maximum depth.

In some embodiments, the support shield forms at least part of a first sidewall of the first gate trench section and at least part of a first sidewall of the second gate trench section.

Pursuant to other embodiments of the present invention, semiconductor devices are provided that comprise a silicon carbide based semiconductor layer structure that comprises a drift region having a first conductivity type, a first trench shielding region having a second conductivity type in the drift region, a second trench shielding region having the second conductivity type in the drift region, and a support shield having the second conductivity type, a first gate trench section extending into the semiconductor layer structure, and a second gate trench section extending into the semiconductor layer structure. The support shield vertically overlaps both the first gate trench section and the second gate trench section, and a maximum depth of the support shield into the semiconductor layer structure differs from a maximum depth of the first trench shielding region into the semiconductor layer structure.

In some embodiments, the maximum depth of the support shield into the semiconductor layer structure is greater than the maximum depth of the first trench shielding region into the semiconductor layer structure.

In some embodiments, the maximum depth of the support shield into the semiconductor layer structure is less than the maximum depth of the first trench shielding region into the semiconductor layer structure.

In some embodiments, an upper portion of the drift region comprises a JFET region that has a higher concentration of first conductivity type dopants than a lower portion of the drift region, and the support shield extends downwardly through the JFET region into the lower portion of the drift region.

In some embodiments, a width of the first trench shielding region is less than a width of the support shield and a width of the second trench shielding region is less than the width of the support shield. In other embodiments, a width of the first trench shielding region is greater than a width of the support shield and a width of the second trench shielding region is greater than the width of the support shield. In some embodiments, a width of the first trench shielding region is less than a width of the first gate trench section. In other embodiments, a width of the first trench shielding region is greater than a width of the first gate trench section.

In some embodiments, the first gate trench section is part of a first gate trench, the second gate trench section is part of a second gate trench, where the second gate trench is spaced apparat from the first gate trench and extends in parallel to the first gate trench.

In some embodiments, the semiconductor device further comprises a third gate trench extending into the semiconductor layer structure, where the first and third gate trenches are the closest gate trenches to the second gate trench, and the support shield comprises a first support shield and the semiconductor layer structure further comprises a second support shield having the second conductivity type in between the second gate trench and the third gate trench.

In some embodiments, a minimum distance between the second gate trench and the second support shield is greater than a minimum distance between the second gate trench and the first support shield.

In some embodiments, the semiconductor device further comprises a first gate dielectric layer in the first gate trench section and a second gate dielectric layer in the second gate trench section, and a lateral thickness of a first portion of the first gate dielectric layer that is on a first sidewall of the first gate trench section that faces the second gate trench section is greater than a lateral thickness of a second portion of the first gate dielectric layer that is on a second sidewall of the first gate trench section, and a lateral thickness of a first portion of the second gate dielectric layer that is on a first sidewall of the second gate trench section that faces the first gate trench section is greater than a lateral thickness of a second portion of the second gate dielectric layer that is on a second sidewall of the second gate trench section.

In some embodiments, a thickness of a bottom portion of the first gate dielectric layer is greater than a thickness of the first portion of the first gate dielectric layer and a thickness of a bottom portion of the second gate dielectric layer is greater than a thickness of the first portion of the second gate dielectric layer.

In some embodiments, the first gate trench section and the second gate trench section are both part of a first gate trench.

In some embodiments, the first gate trench has a closed ring shape when viewed from above.

In some embodiments, the support shield forms at least part of a first sidewall of the first gate trench section and at least part of a first sidewall of the second gate trench section.

Pursuant to additional embodiments of the present invention, semiconductor devices are provided that comprise a silicon carbide based semiconductor layer structure that comprises a drift region having a first conductivity type, a first gate trench and a second gate trench that each extend in the semiconductor layer structure and form a first pair of gate trenches, where the first gate trench is adjacent the second gate trench, a third gate trench and a fourth gate trench that each extend in the semiconductor layer structure and form a second pair of gate trenches, the second pair of gate trenches adjacent the first pair of gate trenches, where the third gate trench is adjacent the fourth gate trench, a first support shield having the second conductivity type in the semiconductor layer structure, an upper portion of the first support shield in between the first gate trench and the second gate trench, a second support shield having the second conductivity type in the semiconductor layer structure, an upper portion of the second support shield in between the third gate trench and the fourth gate trench, and a third support shield having the second conductivity type in the semiconductor layer structure in between the first pair of gate trenches and the second pair of gate trenches. A distance between the third support shield and closest one of the first through fourth gate trenches exceeds a distance between the first support shield and the first gate trench.

In some embodiments, the semiconductor layer structure further comprises a first trench shielding region having a second conductivity type underneath the first gate trench and a second trench shielding region having the second conductivity type underneath the second gate trench, and the first support shield merges into the first and second trench shielding regions.

In some embodiments, a maximum depth of the first support shield exceeds a maximum depth of the first trench shielding region.

In some embodiments, a width of the first trench shielding region is less than a width of the first gate trench.

In some embodiments, the first support shield forms a first sidewall of the first gate trench and a first sidewall of the second gate trench.

Pursuant to further embodiments of the present invention, methods of forming a semiconductor device are provided in which a semiconductor layer structure is provided that has a first conductivity type drift region. Second conductivity type dopants are implanted into the semiconductor layer structure to form a first support shield in the semiconductor layer structure. The semiconductor layer structure is etched to form a first gate trench and a second gate trench in the semiconductor layer structure on opposed sides of the first support shield. Second conductivity type dopants are implanted into a first portion of the semiconductor layer structure that forms a bottom of the first gate trench and into a second portion of the semiconductor layer structure that forms a bottom of the second gate trench to form a first trench shielding region below the first gate trench and a second trench shielding region below the second gate trench.

In some embodiments, the first support shield merges into the first trench shielding region and the second trench shielding region.

In some embodiments, etching the semiconductor layer structure to form the first gate trench and the second gate trench comprises etching away a portion of the first support shield.

In some embodiments, the first support shield vertically overlaps both the first trench shielding region and the second trench shielding region.

In some embodiments, a first maximum depth into the semiconductor layer structure of the first support shield is greater than a second maximum depth into the semiconductor layer structure of the first trench shielding region.

In some embodiments, the semiconductor layer structure further comprises a well region having the second conductivity type on the drift region, an upper portion of the drift region comprises a JFET region that has a higher concentration of first conductivity type dopants than a lower portion of the drift region, and the first support shield extends downwardly through the JFET region into the lower portion of the drift region.

In some embodiments, the first trench shielding region and the second trench shielding region do not extend through the JFET region into the lower portion of the drift region.

In some embodiments, a width of the first trench shielding region is less than a width of the first support shield and a width of the second trench shielding region is less than the width of the first support shield.

In some embodiments, the first trench shielding region is below the first gate trench section and the second trench shielding region is below the second gate trench section.

In some embodiments, the support shield extends in between the first trench shielding region and the second trench shielding region.

### BRIEF DESCRIPTION OF THE DRAWINGS

FIG. 1 is a semi-log graph illustrating the relationship between the lifetime of the gate oxide layer as a function of applied electric field strength.

FIG. 2 is a schematic cross-sectional view of a unit cell of a gate trench power MOSFET having support shields.

FIG. 3A is a schematic top view of a gate trench silicon carbide power MOSFET according to certain embodiments of the present invention.

FIG. 3B is a schematic top view of the gate trench silicon carbide power MOSFET of FIG. 3A with various of the upper metal and dielectric layers removed.

FIG. 3C is a schematic top view of the portion of the gate trench silicon carbide power MOSFET of FIG. 3B shown in the box labelled A in FIG. 3B.

FIG. 3D is a schematic cross-sectional view of the gate trench silicon carbide power MOSFET of FIGS. 3A-3B that is taken along line 3D-3D of FIG. 3C.

FIG. 3E is a schematic cross-sectional view illustrating the primary current path for avalanche currents in the vicinity of one of the pairs of gate trenches of the MOSFET of FIGS. 3A-3D.

FIGS. 4A-4F are schematic cross-sectional views illustrating a method of fabricating the gate trench silicon carbide power MOSFET of FIGS. 3A-3D.

FIG. 5 is a flow chart illustrating a method of fabricating the gate trench silicon carbide power MOSFET of FIGS. 3A-3D.

FIGS. 6A-6C are schematic cross-sectional views of modified versions of the gate trench silicon carbide power MOSFET of FIGS. 3A-3D where the cross-sections are taken along line 3D-3D of FIG. 3C.

FIG. 7 is a schematic cross-sectional view of a gate trench silicon carbide power MOSFET according to further embodiments of the present invention.

FIGS. 8A-8B are schematic cross-sectional views of gate trench silicon carbide power MOSFETs according to still further embodiments of the present invention.

FIGS. 9A and 9B are schematic cross-sectional views of gate trench silicon carbide power MOSFETs according to still further embodiments of the present invention.

FIGS. 10A, 11A and 12A are schematic top views of gate trench silicon carbide power MOSFETs according to still additional embodiments of the present invention with various of the upper metal and dielectric layers removed.

FIGS. 10B, 11B and 12B are schematic cross-sectional views of the gate trench silicon carbide power MOSFET of FIGS. 10A, 11A and 12A that are taken along lines 10B-10B, 11B-11B, and 12B-12B, respectively, of FIGS. 10A, 11A and 12A.

FIG. 13 is a schematic cross-sectional view of a power MOSFET according to further embodiments of the present invention that has widened support shields.

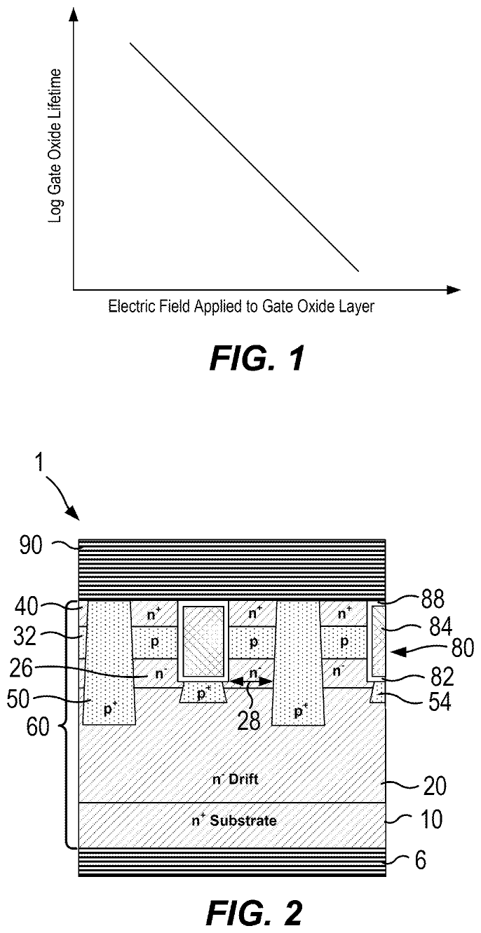

### DETAILED DESCRIPTION

Vertical silicon carbide based power semiconductor devices that have gate trenches such as vertical power MOSFETs and IGBTs are attractive for many applications due to their inherent lower specific on-resistance, which may result in more efficient operation for power switching operations. The channels in a gate trench vertical power device are formed in the sidewalls of the gate trenches, and hence are vertical channels. The carrier mobility in these vertically-oriented sidewall channels may be about 2-4 times higher than the corresponding carrier mobility in the horizontal channel of a standard planar gate (i.e., non-gate trench) vertical power device. The higher carrier mobility provided by the vertically-oriented sidewall channels results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches during reverse blocking operation. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the bottom surface of the semiconductor layer structure) toward the top surface of the semiconductor layer structure. Thus, under reverse blocking operation, the bottom portion of the gate dielectric layer experiences the highest electric field levels. Due to electric field crowding effects, the electric field levels in the lower “corners” of the gate oxide layer at the bottom edges of the gate trench may be particularly high (i.e., the portions of the gate oxide layers that cover the region where the sidewalls of the gate trenches merge into the bottom of the gate trenches). Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer. Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shielding regions” (also called “trench shields” or “bottom shields”) are often provided underneath the gate trenches of gate trench power MOSFETs in order to reduce the electric field levels in the gate oxide layer during reverse blocking operation. These trench shielding regions are formed by doping the portions of the semiconductor layer structure underneath the gate trenches with dopants having the same conductivity type as the dopants included in the channel regions of the device. The trench shielding regions are typically formed via one or more ion implantation processes in which p-type dopant ions (for an n-type MOSFET) are implanted through the bottom surfaces of the gate trenches. The trench shielding regions may, for example, extend downwardly 0.5 to 1.0 microns or more from the bottoms of the gate trenches into the semiconductor layer structure of the device, and are moderately to highly doped regions. The trench shielding regions are electrically connected to the source terminal of the MOSFET by p-type trench shielding region connection patterns. These trench shielding region connection patterns may be in and/or outside the active region of the device.

More recently, gate trench power MOSFETs have been suggested that include additional shielding regions that are referred to as “support shields.” The support shields are formed in the semiconductor layer structure between adjacent gate trenches and, like the trench shielding regions, may comprise moderately or highly doped semiconductor regions having the same conductivity type as the channel regions of the MOSFET. The support shields may, for example, extend to the same depth in the semiconductor layer structure as the trench shielding regions and may be formed by a high-energy ion implantation process. The support shields may directly connect to the source metallization in the active region of the device. An upper portion of each support shield may be more highly doped than a lower portion of the support shield to provide a support shield contact section that forms a low resistivity connection with the source metallization layer. It will be appreciated that, as used herein, references to the “depth” of structures or elements within a semiconductor layer structure refer to the distance that the lowermost surfaces of the structures or elements are from the upper surface of the semiconductor layer structure, where the upper surface of the semiconductor layer structure is the surface opposite the substrate and is also the surface in which the gate trenches are formed.

FIG. 2 is a schematic cross-sectional view of a small portion of a silicon carbide power MOSFET 1 that includes support shields. The cross-section of FIG. 2 shows one full unit cell of the MOSFET 1 and portions of two adjacent unit cells. As shown in FIG. 2, the MOSFET 1 includes a heavily-doped n-type (n+) silicon carbide semiconductor substrate 10. A lightly-doped n-type (n) silicon carbide drift region 20 is provided on the upper surface of the substrate 10. An n-type silicon carbide JFET region 26 is formed in the upper portion of the drift region 20. The JFET region 26 may be more heavily doped than the remainder of the drift region 20. Moderately-doped (p) silicon carbide p-type wells 32 (also referred to as “p-wells”) are provided on the upper surface of the n-type JFET region 26. Heavily-doped (n+) n-type silicon carbide source regions 40 are formed in upper portions of the p-wells 32. The substrate 10, drift region 20, p-wells 32, and source regions 40 are part of a semiconductor layer structure 60 of the MOSFET 1.

The semiconductor layer structure 60 further includes p-type support shields 50 that extend downwardly from an upper portion (e.g., the upper surface) of the semiconductor layer structure 60. The p-type support shields 50 may be moderately (p) and/or heavily doped (p+) silicon carbide regions. As is further shown in FIG. 2, plurality of gate trenches 80 are formed in the upper portion of the semiconductor layer structure 60. The semiconductor layer structure 60 also includes p-type trench shielding regions 54 that are formed underneath the respective gate trenches 80, typically by implanting p-type dopants through the bottoms of the gate trenches 80. The p-type trench shielding regions 54 extend underneath the respective gate trenches 80 for all or substantially all of the length of the gate trench 80 and may be moderately (p) or heavily doped (p+) silicon carbide regions. The p-type support shields 50 and the p-type trench shielding regions 54 act to reduce the electric field levels that form in gate oxide layers (discussed below) during reverse blocking operation.

A gate oxide layer 82 is formed conformally within each gate trench 80, and gate electrodes 84 are formed in the gate trenches 80 on the gate oxide layers 82. An intermetal dielectric pattern 88 covers the gate electrodes 84. A source metallization layer 90 is formed on the intermetal dielectric pattern 88 and on the heavily-doped n-type source regions 40 and upper portions of the support shields 50. A drain contact 6 is formed on the lower surface of the substrate 10

As shown, the p-type support shields 50 may extend downwardly part or all of the way through the JFET region 26. Likewise, the gate trenches 80 and the p-type trench shielding regions 54 thereunder may also extend downwardly part or all of the way through the JFET region 26. The minimum width of the JFET region 26 in between a p-type support shield 50 and an adjacent gate trench 80 (or p-type trench shielding region 54) is referred to as the JFET gap 28. Since during on-state operation the source-to-drain current flows through these JFET gaps 28, the width of the JFET gap 28 has a direct impact on the on-state resistance of MOSFET 1.

While the provision of support shields 50 in gate trench power MOSFET 1 may provide increased protection to the gate oxide layer 82, the support shields 50 may increase the “pitch” of the MOSFET 1. In particular, the pitch of a power MOSFET refers to the distance between adjacent unit cells. When support shields are added to a gate trench power MOSFET, it may be necessary to increase the spacing between adjacent gate trenches 80 to make room for the support shields 50, thereby increasing the pitch, which reduces the integration level of the MOSFET. Adding support shields 50 to MOSFET 1 also typically adds several additional processing steps (e.g., masking, ion implantation and/or mask removal steps), which increases fabrication costs. Thus, there are tradeoffs involved in adding support shields 50 to a gate trench power MOSFET or other power semiconductor device.

Pursuant to embodiments of the present invention, vertical gate trench silicon carbide power MOSFETs (and other power semiconductor devices) are provided that have improved support shield designs. The vertical gate trench silicon carbide power MOSFETs according to embodiments of the present invention may include pairs of closely spaced gate trench sections, where each pair of gate trench sections has a support shield positioned therebetween. The closely spaced gate trench sections that form a pair of gate trench sections may comprise respective sections of the first and second spaced-apart gate trenches in some embodiments. Power semiconductor devices having gate trenches that extend longitudinally in an upper surface of a semiconductor layer structure may have this configuration. Alternatively, the closely spaced gate trench sections that form a pair of gate trench sections may comprise first and second sections of the same gate trench. Power semiconductor devices having cell configurations in which the gate trenches are formed as closed rings may have this configuration In either configuration, the gate trench sections in each pair of gate trench sections may be positioned more closely together than the closest gate trench sections in two different (adjacent) pairs of gate trench sections. In some embodiments, each support shield may form at least portions of the facing sidewalls of the two gate trench sections in the respective pairs of gate trench sections.

A trench shielding region may be provided below each gate trench section. As discussed above, these trench shielding regions may protect the gate oxide layers that are formed in the gate trench sections by reducing the electric field values in the gate oxide layers during reverse blocking operation. The trench shielding regions associated with each pair of gate trench sections may merge into the support shield that is associated with the pair of gate trench sections, so that together the two trench shields and the support shield form one larger implanted region. Each support shield may be directly electrically connected to the source metallization layer (i.e., by extending to the upper surface of the semiconductor layer structure) or may be electrically connected to the source metallization layer through a more heavily doped support shield contact region (which may be considered to be part of the support shield). Since each trench shielding region may merge into an associated support shield (with two trench shielding regions associated with each support shield), the support shields may conveniently provide the electrical connections between the trench shielding regions and the source metallization layer, obviating any need for separate trench shielding region connection patterns.

In some embodiments, each support shield may extend more deeply (i.e., to a greater depth) into the semiconductor layer structure than its associated trench shielding regions. In such embodiments, the support shield may act as the primary current path during an avalanche breakdown event. Using an n-type power MOSFET as an example, during an avalanche breakdown event, current will typically flow from the drain electrode to corners of the p-type regions that extend most deeply into the active region of the semiconductor layer structure. The avalanche current will tend to flow laterally from the corners to the middle the p-type regions that extend most deeply into the active region, and then flow upwardly to the source metallization layer. The avalanche current generates electric fields that extend into surrounding structures. If, for example, the above-described support shields were not provided, then the avalanche currents would flow into the corners of the trench shielding regions and then flow through the trench shielding region connection patterns to the source metallization layer. This would bring the avalanche currents in close proximity to the portions of the gate oxide layers that line the bottom corners of the gate trenches, and the high electric field values generated by the avalanche current in the gate oxide layers that line the bottom corners of the gate trenches tends to stress/damage those portions of the gate oxide layers. Electric field crowding effects that occur in these bottom corner regions may further increase the amount of stress/damage, potentially resulting in device failure. By routing the avalanche currents farther away from the bottom corners of the gate trenches (and most particularly, away from the bottom corners of the gate trenches that are adjacent channel regions of the devices, as will be discussed in further detail herein), the power semiconductor devices according to embodiments of the present invention may exhibit improved reliability.

Since support shields are formed in between the gate trench sections of each pair of gate trench sections, channel regions may only be formed in the outer sidewall of each gate trench section in a pair of gate trench sections, as the support shield may form the inner sidewall of each gate trench section. This may reduce the overall amount of channel region available for conducting current during on-state operation. However, the gate trench sections in each pair of gate trench sections may be positioned more closely together than normal, since channels are not formed in the inner sidewalls and since no source region may be provided in between the gate trench sections of the pair (and hence no connection between a source region and the source metallization layer), and thus more gate trench sections may be provided in the device than in a corresponding conventional power semiconductor device. This helps make up for the reduced amount of channel region associated with each gate trench section. In addition, since, as discussed above, the support shields that are disposed in between the respective pairs of gate trench sections merge into the trench shielding regions, the need for trench shielding region connection patterns may be reduced or eliminated, which again increases the amount of available channel area as compared to a conventional power semiconductor device. Thus, the power semiconductor devices according to embodiments of the present invention may provide good on-state performance (e.g., handle high current densities) while exhibiting improved reliability and/or improved reverse breakdown performance.

In some embodiments, the gate dielectric layers of the power semiconductor devices according to embodiments of the present invention may have non-uniform thicknesses. In particular, the thickness of the portions of the gate dielectric layers lining the inner sidewalls and/or the bottoms of the gate trench sections of each pair of gate trench sections may be thicker than the portions of the gate dielectric layers lining the outer sidewalls of the gate trench sections of each pair of gate trench sections. In particular, the thickness of the portions of the gate dielectric layers lining the outer sidewalls of the gate trench sections of each pair of gate trench section may be set to optimize the switching performance of the power semiconductor device, since these portions of the gate dielectric layers are adjacent the channel regions in the semiconductor layer structure. Since the portions of the gate dielectric layers lining the inner sidewalls and the bottoms of the gate trench sections are not adjacent any channel regions, the gate dielectric layers may be made thicker in these regions without impacting device performance. As discussed above, thickening the gate dielectric layers advantageously reduces its susceptibility to breakdown. Moreover, as will be discussed in greater detail below, it is the portions of the gate dielectric layers lining the inner sidewalls and/or the bottoms of the gate trench sections of each pair of gate trench sections that are subject to the highest electric fields during an avalanche breakdown event, and hence thickening these portions of the gate dielectric layers may be particularly helpful in improving reliability.

While some of the power semiconductor devices according to embodiments of the present invention have support shields that extend more deeply into the semiconductor layer structure than their associated trench shielding regions, it will be appreciated that embodiments of the present invention are not limited thereto. Depending upon the application, the requirements for on-state resistance performance, reverse breakdown performance, and reliability performance will differ, as will the likelihood of device failure due to avalanche breakdown generated stress on a gate oxide layer versus the stress generated over time during reverse blocking operation. Thus, for example, in some embodiments, protecting the gate oxide layer lining the outer bottom corners of the gate trenches may be most important, and in such applications it may be beneficial to have the trench shielding regions extend more deeply into the semiconductor layer structure than the support shields.

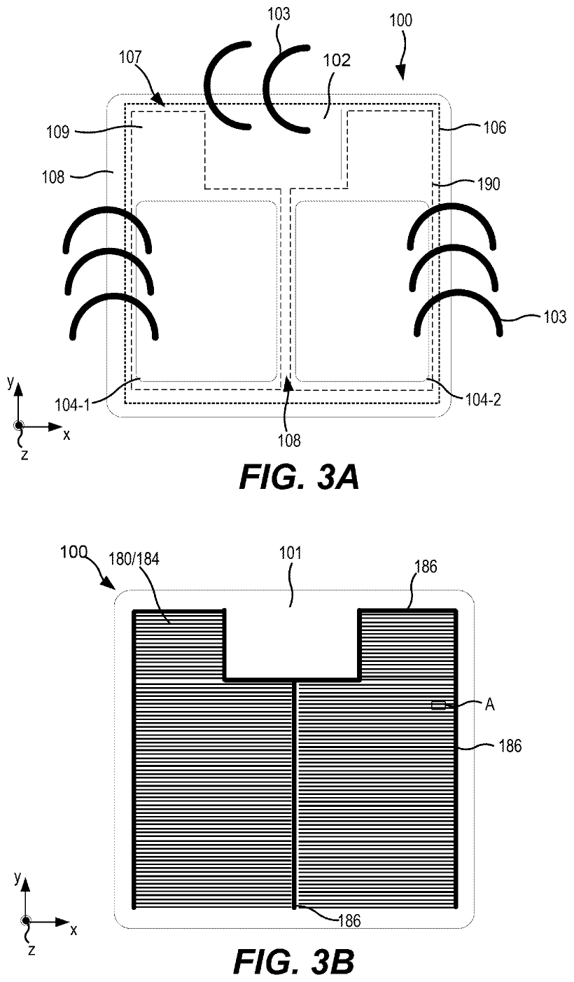

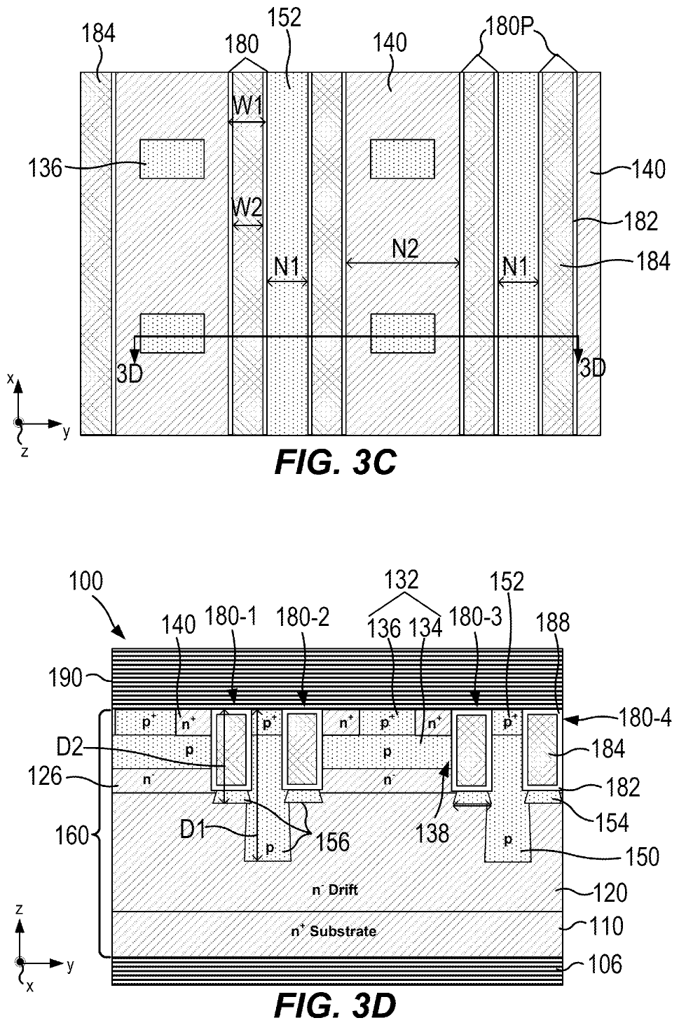

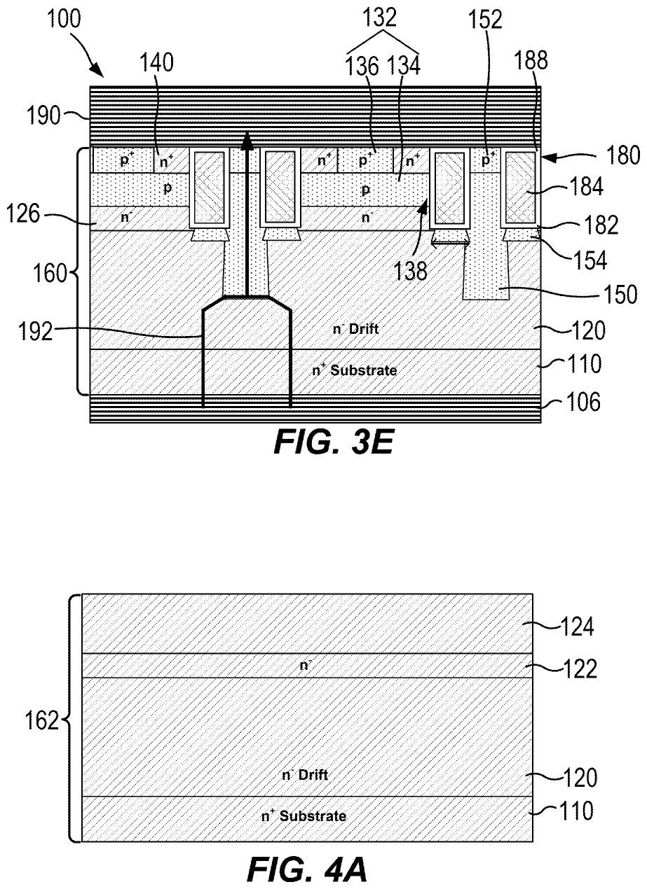

Embodiments of the present invention will now be described in more detail with reference to FIGS. 3A-13. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top view of a gate trench silicon carbide power MOSFET 100 according to certain embodiments of the present invention. FIG. 3B is a schematic plan view of the power MOSFET 100 with various top-side metal and dielectric layers thereof omitted to show the gate electrodes and gate buses. FIG. 3C is a schematic top view of the portion of the gate trench silicon carbide power MOSFET 100 of FIG. 3B shown in the box labelled A in FIG. 3B. FIG. 3D is a schematic cross-sectional view of about two unit cells of the gate trench silicon carbide power MOSFET 100 that is taken along line 3D-3D of FIG. 3C. It will be appreciated that the thicknesses of various of the layers and regions in FIGS. 3A-3D are not necessarily drawn to scale. The same is true with respect to the other figures included in this application.

The power MOSFET 100 includes a semiconductor layer structure 160 (see FIG. 3D) that comprises one or more semiconductor substrates and/or layers. At least one of the semiconductor layers in the semiconductor layer structure 160 may be a silicon carbide layer. Various metal and/or dielectric layers are formed on either side of the semiconductor layer structure 160 and embedded in the semiconductor layer structure 160.

As shown in FIG. 3A, the top-side metal layers include a gate bond pad 102 and one or more source bond pads 104-1, 104-2 that are formed on the upper side of the semiconductor layer structure 160. A metal drain pad 106 (shown as a dotted box in FIG. 3A) is provided on the bottom side of the semiconductor layer structure 160. The gate bond pad 102, the source bond pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source metallization layer 190 (indicated by the dashed boxes in FIG. 3A) that electrically connects certain regions of the semiconductor layer structure 160 to the source bond pads 104-1, 104-2. The source bond pads 104-1, 104-2 may be portions of the source metallization layer 190 that are exposed through openings in the protective layer 109 or may be separate metal layers. The source metallization layer 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 103 are shown in FIG. 3A that may be used to connect the gate bond pad 102 and the source bond pads 104 to external circuits or the like. The drain pad 106 on the bottom side of power MOSFET 100 may be connected to an external circuit through, for example, an underlying submount (not shown).

FIG. 3B is another plan view of power MOSFET 100 with the gate and source bond pads 102, 104, the polymide layer 109, the source metallization layer 190, the intermetal dielectric layers 188 and various other metal and dielectric layers removed to show the gate electrodes 184 that are formed in the gate trenches 180 in the semiconductor layer structure 160. A patterned field oxide layer (not shown) is formed on the semiconductor layer structure 160 in the inactive region 108 of the MOSFET 100. The field oxide layer may be a relatively thick oxide layer (e.g., ten to twenty times thicker than the gate oxide layers that are discussed below). A polysilicon layer 101 may be formed on the field oxide layer and may be formed in the region where the gate bond pad 102 is formed so that the gate bond pad 102 vertically overlaps the field oxide layer and the polysilicon layer 101. As used herein, two elements of a semiconductor device are considered to “vertically overlap” if an axis that is perpendicular to the major surfaces of a semiconductor layer structure of the semiconductor device intersects both elements.

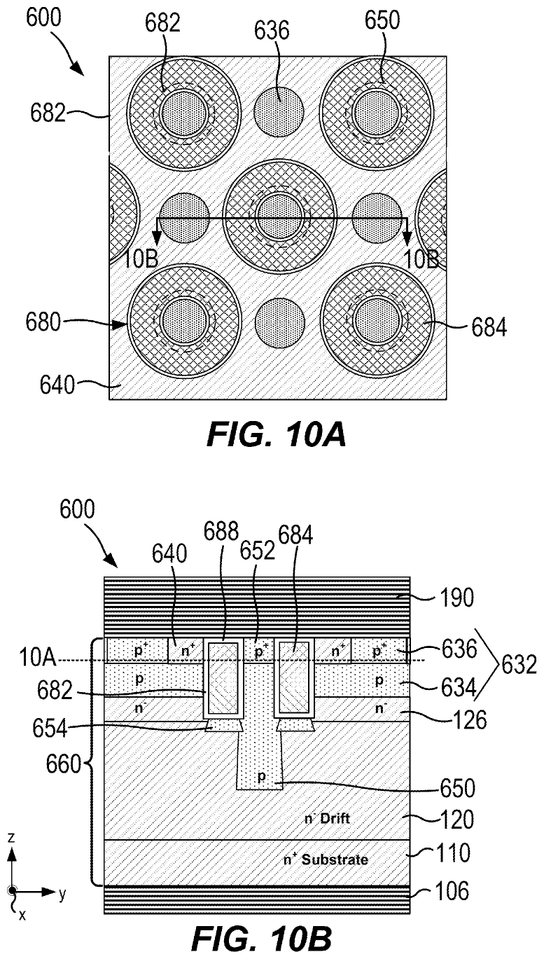

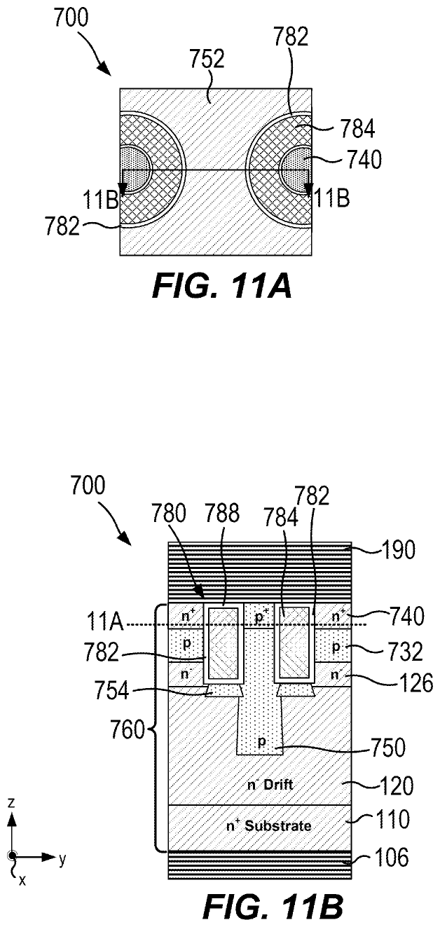

One or more gate buses 186 are provided that extend around the periphery of the active region 107. The field oxide layer typically runs underneath each gate bus 186 as well as underlying the polysilicon layer 101 that is underneath the gate bond pad 102. The gate buses 186 are electrically connected to the gate bond pad 102, often through gate resistors (not shown). A plurality of gate trenches 180 (see FIG. 3D) are formed throughout the active region 107. A gate electrode 184 is formed in each gate trench 180. In the depicted MOSFET 100, the gate electrodes 184 extend horizontally across the semiconductor layer structure 160. In other cases, the gate electrodes 184 may extend vertically across the semiconductor layer structure 160, both horizontally-extending and vertically-extending gate electrodes 184 can be provided to form a grid-like gate electrode structure. The gate electrodes 184 may alternatively comprise closed rings in embodiments in which the semiconductor device has a cell configuration, as is discussed below with reference to FIGS. 10A-12B. The gate electrodes 184 may be connected to the gate pad 102 through the gate buses 186. The gate electrodes 184 may comprise, for example, a doped polysilicon pattern. The gate buses 186 may comprise polysilicon and/or metal structures in example embodiments and typically are in the inactive region 108 of power MOSFET 100.

FIG. 3C is a schematic top view of the portion of the gate trench silicon carbide power MOSFET 100 of FIG. 3B shown in the box labelled A. In FIG. 3C, various dielectric and metal layers are omitted so that the upper surface of the semiconductor layer structure 160 is visible, as are the gate trenches 180, and the gate oxide layers 182 and gate electrodes 184 formed therein. As shown in FIG. 3C, the longitudinal axes of each gate trench 180 extends in the x-direction so that the gate trenches 180 extend in parallel to each other. The gate trenches 180 extend into the upper surface of the semiconductor layer structure 160. The gate trenches 180 are arranged as pairs of gate trenches 180P, with the gate trenches 180 in each pair 180P being located closer together (here by a distance N1) that is less than a distance N2 between adjacent gate trenches 180 from two adjacent pairs of gate trenches 180P. Heavily-doped n-type source regions 140 are formed in the upper surface of the semiconductor layer structure 160 in between adjacent pairs of gate trenches 180P. The source regions 140 extend longitudinally in the x-direction. Heavily-doped p-type well contact regions 136 are formed as islands within each n-type source region 140. Finally, support shield contact regions 152 are provided in the upper surface of the semiconductor layer structure 160 in between the gate trenches 180 of each pair of gate trenches 180P.

FIG. 3D is a schematic cross-sectional view taken along line 3D-3D of FIG. 3C that illustrates almost two unit cells of the power MOSFET 100. As shown in FIG. 3D, the power MOSFET 100 includes an n-type silicon carbide semiconductor substrate 110. The substrate 110 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 110 may have a doping concentration of, for example, between 1×10¹⁸ atoms/cm³ and 1×10²¹ atoms/cm³, although other doping concentrations may be used. The substrate 110 may be relatively thick in some embodiments (e.g., 20-100 microns or more). It should be noted that while the substrate 110 is depicted as a relatively thin layer, this is done to allow enlarging the thickness of other layers and regions in FIG. 3D, and it will be appreciated that the substrate 110 will typically be much thicker than shown. The thickness of various other layers of power MOSFET 100 likewise may not be shown to scale in order to allow other portions of the devices to be enlarged in the figures.

A lightly-doped n-type (n-) silicon carbide drift layer 120 (which also may be referred to herein as a drift region 120) is provided on an upper surface of the substrate 110. Typically, the drift layer 120 is formed via an epitaxial growth process and is doped during growth. The n-type drift region 120 may have, for example, a doping concentration of 5×10¹⁵ to 5×10¹⁷ dopants/cm³. The n-type drift region 120 may be a thick region, having a vertical height above the substrate 110 of, for example, 3-50 microns, and can be doped during growth. An upper portion of the n-type drift region 120 may comprise an n-type JFET region 126 that is more heavily doped than the lower portion of the n-type drift region 120. The n-type JFET region 126 may have an n-type dopant concentration of, for example, 5×10¹⁶ to 1×10¹⁸. The n-type JFET region 126 is considered to be part of the drift region 120.

The drift layer 120 and the substrate 110 together act as a common drain region for the power MOSFET 100. The drain pad 106 is formed on the substrate 110 opposite the drift region 120.

Still referring to FIG. 3D, a plurality of moderately-doped (p) p-type silicon carbide well regions 132 (also referred to herein as p-wells 132) are provided on the upper surface of the n-type JFET region 126. Each p-well 132 may comprise a moderately-doped (p) lower region 134 and a more heavily doped p-type upper portion 136 that acts as a well contact region to provide a low resistance connection between the source metallization layer 190 and the moderately-doped (p) lower region 134 of the p-well 132. The lower portion 134 of each p-well 132 may be formed either by epitaxial growth or by ion implantation. In example embodiments, the lower regions 134 of the p-wells 132 may have a p-type dopant concentration of, for example, between 5×10¹⁶ to 1×10¹⁸. The more heavily doped upper portion 136 of each p-well 132 may have a p-type dopant concentration of, for example, between 5×10¹⁷ to 1×10²², and may be formed, for example, by ion implantation.

A plurality of heavily-doped (n+) n-type silicon carbide source regions 140 are formed on the lower regions 134 of the p-wells 132. The more heavily doped upper portions 136 of the p-wells 132 may be formed as islands within the source regions 140, as shown best in FIG. 3C. The source regions 140 may be formed by ion implantation. Each source region 140 may have a doping concentration of, for example, between 1×10¹⁹ atoms/cm³ and 5×10²¹ atoms/cm³.

As is further shown in FIG. 3D, p-type support shields 150 are provided that extend downwardly from the upper portion (e.g., the upper surface) of the semiconductor layer structure 160 into the silicon carbide drift region 120. It will be appreciated that the p-type support shields 150 are not part of the n-type drift region 120 but rather are formed within the drift region 120 and are typically formed by converting selected portions of the drift region 120 into the p-type support shields 150. The p-type support shields 150 may be moderately and/or heavily doped (p+) silicon carbide regions. For example, each p-type support shield 150 may have a doping concentration between about 5×10¹⁶ and 1×10²². In other embodiments, each p-type support shield 150 may have a doping concentration between about 1×10¹⁸ and 1×10²⁰, between about 1×10¹⁹ and 1×10²⁰, between about 1×10¹⁷ and 1×10¹⁹, between about 1×10¹⁷ and 1×10²⁰, or between about 1×10¹⁸ and 1×10²¹. As shown in FIG. 3D, an upper portion 152 of each support shield 150 may be more heavily doped p-type than the remainder of the support shield 150. These regions 152 may be referred to herein as support shield contact regions 152 and may be considered to be part of their associated support shields 150. The support shield contact regions 152 may provide a low resistance connection between the source metallization layer 190 and the remaining portions of the respective support shields 150. In example embodiments, each p-type support shield 150 may extend to a depth of between 0.1 microns and 4.0 microns from the upper surface of the semiconductor layer structure 160. In other embodiments, the depth of each p-type support shield 150 may be between 1.0 and 3.0 microns, between 1.0 and 2.5 microns, between 1.5 and 3.0 microns, between 1.5 and 2.5 microns, or between 0.5 and 2.5 microns. Any of the above dopant concentration ranges for the p-type support shields 150 may be matched with any of the above-listed depths for the p-type support shields 150. The p-type support shields 150 may act to reduce the electric field levels that form in gate oxide layers during device reverse blocking operation, as will be discussed in greater detail below.

As shown in FIG. 3D, a lateral width of each support shield 150 increases as the support shield extends further into the semiconductor layer structure 160. Herein, the width of a support shield in a gate trench MOSFET or other power semiconductor device having a stripe configuration refers to the extent of the support shield in the y-direction of FIG. 3D (i.e., in a direction that is parallel to a major surface of the semiconductor layer structure and perpendicular to the sidewalls of the gate trenches). This occurs because the support shields are formed using standard ion implantation techniques where the dopant ions are implanted at high energy at an angle of 90° into the upper surface of the semiconductor layer structure 160. As the dopant ions pass through the semiconductor material, they collide with atoms in the crystal lattice, which may redirect the dopant ions in different directions so that at least some of the dopant ions will move both vertically and laterally through the crystal lattice. The farther a dopant ion is implanted into the semiconductor layer structure 160, the more likely that the dopant ion includes some degree of lateral movement. This lateral movement results in the implanted region spreading out laterally with increased depth, which is often referred to as “blooming.”

As discussed above, a plurality of gate trenches 180 are formed in the upper surface of the semiconductor layer structure 160. P-type trench shielding regions 154 are formed underneath the respective gate trenches 180 and may extend underneath the respective gate trenches 180 for all or substantially all of the length of the gate trench 180. The p-type trench shielding regions 154 may be moderately or heavily doped (p+) silicon carbide regions. For example, each p-type trench shielding region 154 may have a doping concentration between about 1×10¹⁷ and 1×10²¹. In other embodiments, each p-type trench shielding region 154 may have a doping concentration between about 1×10¹⁸ and 1×10²⁰, between about 1×10¹⁹ and 1×10²⁰, between about 1×10¹⁷ and 1×10²⁰, or between about 1×10¹⁸ and 1×10²¹. In example embodiments, a lower surface of each p-type trench shielding region 154 may be at a depth of between 0.5 and 3.0 microns from the upper surface of the semiconductor layer structure 160. In other embodiments, the depth of each p-type trench shielding region 154 may be between 1.0 and 3.0 microns, between 1.0 and 2.5 microns, between 1.5 and 3.0 microns, between 1.5 and 2.5 microns, or between 0.5 and 2.5 microns. Any of the above dopant concentrations may be matched with any of the above-listed depths for the p-type trench shielding regions 154. The p-type trench shielding regions 154 may act to reduce the electric field levels that form in gate oxide layers (discussed below) during device operation, as will be discussed in greater detail below. The p-type trench shielding regions 154 may be doped to have a higher p-type dopant concentration, a lower p-type dopant concentration, or approximately the same p-type dopant concentration as the lower portions of the p-type support shields 150. The doping concentration of the p-type trench shielding regions 154 may be different from the doping concentration of the p-type support shields 150. Thus, it will be appreciated that any of the dopant concentrations set forth above for the p-type trench shielding regions 154 may be combined with any of the dopant concentrations for the p-type support shields 150 that are set forth above.

As shown in FIG. 3D, the p-type trench shielding regions 154 may merge into the p-type support shields 150 to form a larger implanted region 156. As discussed above, each p-type support shield 150 is electrically connected to the source metallization layer 190. Since the trench shielding regions 154 merge into the support shields 150, the support shields 150 act to electrically connect the trench shielding regions 154 to the source metallization layer 190.

The n-type silicon carbide substrate 110, the n-type silicon carbide drift layer 120 (including the JFET region 126), the p-type silicon carbide well regions 132 (including portions 134 and 136), the n-type silicon carbide source regions 140, the p-type silicon carbide support shields 150 (including support shield contact regions 152) and the p-type silicon carbide trench shielding regions 154 may together comprise the semiconductor layer structure 160 of the power MOSFET 100.

A gate oxide layer 182 is provided in each gate trench 180 to cover the sidewalls and bottom surface of the gate trench 180. Each gate oxide layer 182 may comprise, for example, a silicon oxide (SiO₂) pattern. The gate oxide layers 182 may or may not be connected to each other outside the view of FIG. 3D. As shown in FIG. 3D, in some embodiments, the gate oxide layers 182 may be formed generally conformally within the respective gate trenches 180.

A gate electrode 184 is formed in each gate trench 180 on the gate oxide layer 182. The gate electrodes 184 may comprise conductive material such as a silicide (e.g., NiSi, TiSi, WSi, CoSi), doped polycrystalline silicon (poly-Si), and/or a stable conductor. Other suitable materials for the gate electrode include various metals such as Ti, Ta or W or metal nitrides such as TiN, TaN or WN. The gate oxide layers 182 may insulate the gate electrodes 184 from the semiconductor layer structure 160, thereby preventing the gate electrodes 184 from short circuiting to the semiconductor layer structure 160. Each gate electrode 184 may connect to one of the gate buses 186 (see FIG. 3B). In the depicted embodiment, the gate electrodes 184 are recessed so that the upper surface of each gate electrode 184 is below an upper surface of the semiconductor layer structure 160. It will be appreciated that in other embodiments the gate electrodes 184 may extend above and onto the upper surface of the semiconductor layer structure 160, with the gate oxide layer 182 insulating the gate electrodes 184 from the upper surface of the semiconductor layer structure 160.

Intermetal dielectric layers 188 are formed that cover each gate electrode 184. The intermetal dielectric layers 188 insulate the source metallization layer 190 from the gate electrodes 184.

A source metallization layer 190 is formed on the upper surface of the semiconductor layer structure 160 and on the intermetal dielectric layers 188. Herein, the source metallization layer 190 may also be referred to as the “source contact.” The source metallization layer 190 may comprise a single metal layer or multiple metal layers. Typically multiple metal layers are provided, as the source metallization layer 190 may include, for example, a single layer or multi-layer adhesion layer that contacts the semiconductor layer structure 160, one or more barrier layers, and a bulk metal layer (e.g., an aluminum layer).

The power MOSFET 100 may be turned on by applying a gate bias voltage that is above a threshold level to the gate pad 102. The gate bias voltage is transferred to the gate electrodes 184 via the gate buses 186 and creates conductive n-type inversion layers in the portions of the moderately doped portions 134 of the p-wells 132 that are adjacent the gate trenches 180. These regions of the moderately doped portions 134 of the p-wells 132 are referred to herein as channel regions 138 as current flows from the source regions 140 to the drift region 120 through these channel regions 138 during on-state operation. The channel regions 138 are vertically oriented (i.e., extend in the z direction) as the current flows downwardly from the source regions 140, through the channel regions 138 to the drift region 120, substrate 110 and drain contact 106.

The support shields 150 (including the support shield contact regions 152) form the inner sidewalls of each gate trench 180 in each pair of gate trenches 180P such that only p-type semiconductor material extends next to the inner sides of the gate electrodes 184 that are in the gate trenches 180 of each pair of gate trenches 180P. As such, source regions 140 are not provided in between the two gate trenches 180 that form each pair of gate trenches 180P, and channel regions 138 are not formed along the inner sidewalls of the gate trenches 180. Consequently, as shown in FIG. 3C, the edge-to-edge distance N1 between the two gate trenches 180 in a pair of gate trenches 180P may be less than, and potentially significantly less than, the edge-to-edge distance N2 between the adjacent gate trenches 180 of two different pairs of gate trenches 180P. This allows the density of gate trenches 180 to be increased as compared to a conventional device. In an example embodiment, the distance N1 may be less than 70% the distance N2. In other embodiments, the distance N1 may be less than 50% the distance N2, less than 40% the distance N2, less than 30% the distance N2, or even less than 20% the distance N2. In some embodiments, the distance N1 may be in between 25-50% the distance N2.

The edge-to-edge distance N1 between the two gate trenches 180 in a pair of gate trenches 180P may, in some cases, be less than the widths W1 of the gate trenches 180. The edge-to-edge distance N1 between the two gate trenches 180 in a pair of gate trenches 180P may, in other cases, be less than the widths W2 of the gate electrodes 184 that are in the two gate trenches 180 in the pair of gate trenches 180P.

As noted above, in some embodiments, each support shield 150 may extend more deeply (i.e., to a greater depth) into the semiconductor layer structure 160 than its associated trench shielding regions 154. In such embodiments, the support shields 150 may act as the primary current path during an avalanche breakdown event. As known in the art, avalanche breakdown refers to a condition in a MOSFET (or other semiconductor device) during reverse blocking operation where the electric field across the p-n junctions gets high enough such that it frees the carriers from their covalent bonds, resulting in a so-called avalanche current flowing from the drain pad to the source metallization layer. Assuming an n-type power MOSFET as an example, the avalanche current flows from the drain into the n-type substrate and n-type drift region of the power MOSFET. If p-type support shields or trench shielding regions extend deeper into the semiconductor layer structure than the p-wells of the MOSFET, the avalanche current will then primarily flow into whichever of the support shields/trench shielding regions extend deepest into the semiconductor layer structure. The avalanche current flow will primarily pass from the drift region into the support shields/trench shielding regions at lower corners of the support shields/trench shielding regions, and will then flow upwardly toward the source metallization layer. If the support shields extend deeper into the semiconductor layer structure than the trench shielding regions, then the avalanche current will primarily flow into the bottom corners of the support shields and then flow upwardly, with the heaviest current in the center of each support shield, to the source metallization layer. If the trench shielding regions extend deeper into the semiconductor layer structure than the support shields, then the avalanche current will primarily flow into the bottom corners of the trench shielding regions and then flow through the trench shielding region connection patterns to the source metallization layer.

The avalanche current generates electric fields that extend into surrounding structures. If, for example, a power MOSFET does not include support shields or has support shields that are shallower than the trench shielding regions so that the avalanche currents flow into the trench shielding regions, then the avalanche currents will flow in close proximity to the portions of the gate oxide layers that line the bottom corners of the gate trenches. The avalanche current generates strong electric fields which extend into surrounding structures, including the gate oxide layers that line the bottom corners of the gate trenches. These electric fields may damage the gate oxide layers, particularly in the corner regions where electric field crowding effects act to increase the intensity of the electric field.

Since power MOSFET 100 has support shields 150 that extend deeper into the semiconductor layer structure 160 than the trench shielding regions 154, any avalanche currents will primarily flow into the support shields 150. As shown in FIG. 3E, the avalanche currents 192 tend to flow laterally along the bottoms of the support shields 150 to the middle thereof, and then flow upwardly through the support shields 150 to the source metallization layer 190. Since the support shields 150 extend significantly deeper into the semiconductor layer structure 160 (as compared to the trench shielding regions 154), the heaviest avalanche currents will not flow directly adjacent the gate oxide layers 182 lining the bottom corners of the gate trenches 180. Moreover, the avalanche currents are routed far away from the portions of the gate oxide layers 182 that line the outer bottom corner of each gate trench 180, which is the region of each gate oxide layer 182 that is subject to the highest electric fields during reverse blocking operation, and hence the region that is most likely to have been damaged during normal device operation. Consequently, the design of power MOSFET 100 protects the weakest portion of each gate oxide layer 182 during an avalanche breakdown event, decreasing the possibility of device failure during an avalanche breakdown event.

Since no source region 140 is formed in between the gate trenches 180 forming each pair of gate trenches 180P, the channel regions 138 are only formed in the outer sidewall of each gate trench 180. This reduces the overall amount of channel region available for conducting current during on-state operation as compared to the power MOSFET 1 shown in FIG. 2. However, as discussed above, the two gate trenches 180 forming each pair of gate trenches 180P may be positioned more closely together than normal, and thus more gate trenches 180 may be provided in the device than in the MOSFET 100, which helps make up for the reduced amount of channel region associated with each gate trench 180. In addition, since the support shields 150 electrically connect the trench shielding regions 154 to the source metallization layer 190, the need for separate trench shielding region connection patterns may be eliminated in the MOSFET 100. While trench shielding region connection patterns are not shown in the cross-section of FIG. 2, they are typically implemented within the active region of a power MOSFET and reduce the amount of channel region available as compared to a MOSFET that does not include trench shielding regions. Thus, the power MOSFET 100 may have comparable on-state current carrying capacity to the MOSFET 1 of FIG. 2, while also exhibiting improved reliability and/or improved reverse breakdown performance.

In addition to having improved robustness with respect to avalanche breakdown events, the power MOSFET 100 may also exhibit improved robustness during normal operation. As discussed above, one common failure mechanism in power semiconductor devices such as power MOSFETs is device failure due to breakdown of the gate oxide layer over time due to electric field stress thereto during reverse blocking operation. Since the lifetime (i.e., time until breakdown) of a gate oxide layer is a function of the intensity of the electric field in the gate oxide layer during device operation, one way to reduce the instances of device failure is to design the MOSFET to have reduced peak electric field values in the gate oxide layer during reverse blocking operation.

During reverse blocking operation, the electric field extends upwardly from the bottom of the MOSFET 100. As such, strong electric fields may extend upwardly toward the lower portion of the gate oxide layers 182. The p-type support shields 150 and the p-type trench shielding regions 154 act as shields that reduce the electric field values in the vicinity thereof. Since the support shields 150 are formed deep into the semiconductor layer structure 160, they may suppress the electric field values in the vicinity of the gate trenches 180. The electric fields will tend to protrude upwardly on either side of each support shield 150, so the trench shielding regions 154 are provided that provide additional electric field expression directly underneath each gate trench 180.

A general tradeoff exists between the on-state resistance of a power MOSFET having trench shielding regions and/or support shields and the reliability of such a power MOSFET (or the reverse blocking voltage rating of the device, since reliability may always be improved by only operating the MOSFET at lower reverse blocking voltage levels). In particular, having larger p-type shield regions 150, 154 located close to the gate trenches 180 improves reliability, but acts to increase the on-state resistance as these p-type regions channel the on-state currents through narrowed regions of the drift region 120. By providing the support shields 150 between the gate trenches 180 of each pir of gate trenches 180P the reliability may be improved with little reduction in the on-state resistance, as the support shields 150 are located far from the channel regions 138 and hence have little (if any) current crowding effects. Moreover, the deep support shields 150 allow the depth of the trench shielding regions 154 to be reduced, thereby reducing the current crowding effects attributable to the trench shielding regions 154.

As noted above, when no p-type shielding 150, 154 is provided, the lower portions of each gate oxide layer 182 are subjected to the highest electric fields, as the electric field strength generally decreases with increasing distance from the substrate 110. Moreover, due to electric field crowding effects, the portions of each gate oxide layer 182 that are most susceptible to reverse breakdown are the portions of the gate oxide layer 182 lining the bottom corners of each gate trench 180, as the sharp corners act to concentrate (i.e., increase the value of) the electric fields in these regions. If the lateral (y-direction) widths of the trench shielding regions 154 are increased, the trench shielding regions 154 may provide enhanced protection to the portions of the gate oxide layers 182 lining the outer bottom corners of the gate trenches 180. However, as the lateral widths of the trench shielding regions 154 are increased, the trench shielding regions 154 increasingly act to funnel the on-state currents, which increases the on-state resistance. Thus, the lateral widths of the trench shielding regions 154 may be selected to provide a desired tradeoff between on-state resistance and reliability performance. In the power MOSFET 100 of FIGS. 3A-3D, the lateral width of each trench shielding region 154 is less than the lateral width of its associated gate trench 180, which will tend to improve the on-state resistance performance.

Still referring to FIG. 3D, it can be seen that MOSFET 100 includes a silicon carbide based semiconductor layer structure 160 that comprises, among other things, a drift region 120 having a first (n) conductivity type and an implanted region 156 having a second (p) conductivity type on the drift region 120. First and second gate trench sections 180-1, 180-2 extend into the semiconductor layer structure 160. In the embodiment of FIGS. 3A-3D, the first gate trench section is all or part of a first gate trench 180-1, and the second gate trench section is all or part of a second gate trench 180-2, where the second gate trench 180-2 is spaced apparat from the first gate trench 180-1 and extends in parallel to the first gate trench 180-1. Thus, in the description below, reference numeral 180-1 will be used to refer to the first gate trench section and reference numeral 180-2 will be used to refer to the second gate trench section. The implanted region 156 may comprise a first trench shielding region 154 that is below the first gate trench section 180-1, a second trench shielding region 154 that is below the second gate trench section 180-2 and a support shield 150 that is at least partially in between the first gate trench section 180-1 and the second gate trench section 180-2. A first maximum depth D1 into the semiconductor layer structure 160 of a first portion 150 of the implanted region 156 that is between the first gate trench section 180-1 and the second gate trench section 180-2 is different than a second maximum depth D2 into the semiconductor layer structure 160 of a second portion 154 of the implanted region 156 that extends downwardly underneath the first gate trench section 180-1.

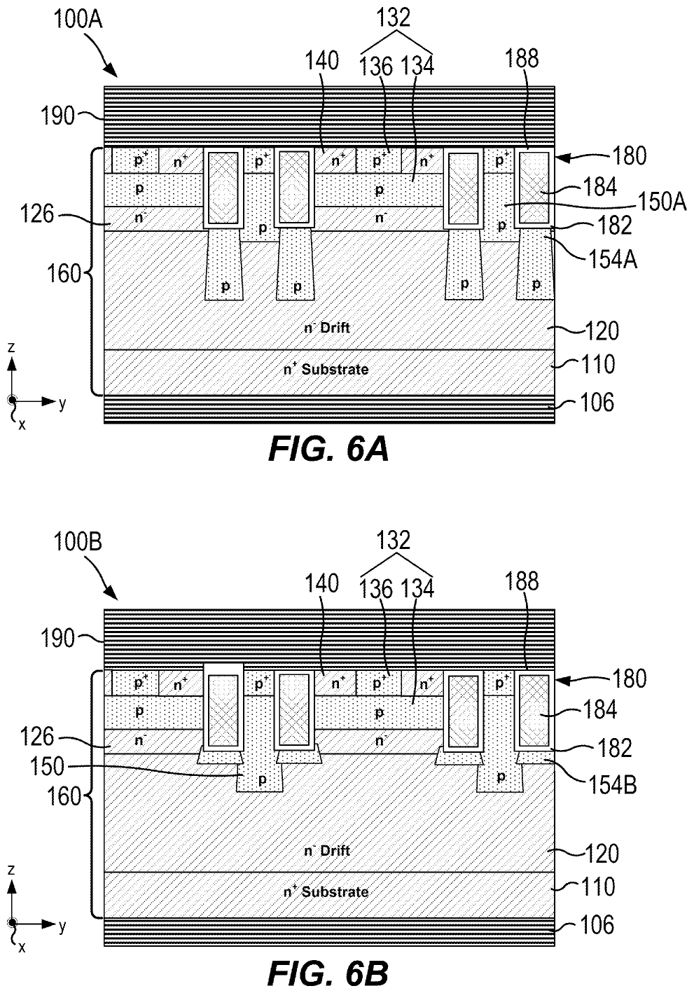

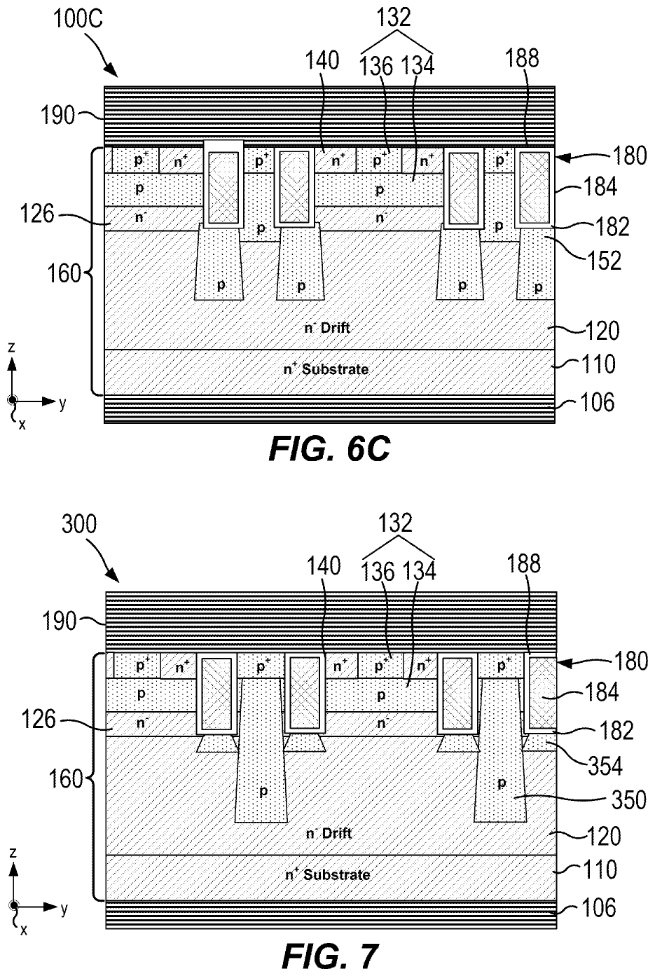

As shown in FIG. 3D, in some embodiments the first maximum depth D1 may be greater than the second maximum depth D2. As discussed below with reference to FIGS. 6A and 6C, in other embodiments the first maximum depth D1 may be less than the second maximum depth D2.

The semiconductor layer structure 160 may further comprise a well region 132 having the second conductivity type on the drift region 120, and an upper portion of the drift region 120 may be a JFET region 126 that has a higher concentration of first conductivity type dopants than the lower portion of the drift region 120. In such embodiments, the support shield 150 may extend downwardly through the JFET region 126 into the lower portion of the drift region 120. In some cases the first and second trench shielding regions 154 may extend through the JFET region 126 into the lower portion of the drift region 120, while in other embodiments the first and second trench shielding regions 154 may not extend through the JFET region 126 into the lower portion of the drift region 120. In some embodiments, the widths of the first and second trench shielding regions 154 may each be less than a width of the support shield 150. In other embodiments, the widths of the first and second trench shielding regions 154 may each be greater than a width of the support shield 150. In some embodiments, the widths of the first and second trench shielding regions 154 may be less than a width W1 of the first gate trench 180-1.

Still referring to FIG. 3D, it can also be seen that MOSFET 100 includes a silicon carbide based semiconductor layer structure 160 that comprises, among other things, a drift region 120 having a first (n) conductivity type, a first trench shielding region 154 having a second (p) conductivity type within the drift region 120, a second trench shielding region 154 having the second (p) conductivity type within the drift region 120, and a support shield 150 having the second (p) conductivity type. First and second gate trench sections 180-1, 180-2 extend into the semiconductor layer structure 160. A maximum depth of the support shield 150 into the semiconductor layer structure 160 differs from a maximum depth of the first trench shielding region 154 into the semiconductor layer structure 160, namely the maximum depth D1 of the support shield 150 is greater than the maximum depth D2 of the first trench shielding region 154. The support shield 150 may vertically overlap both the first gate trench section 180-1 and the second gate trench section 180-2. Additionally or alternatively, the support shield 150 may form at least part of a first sidewall of the first gate trench section 180-1 and at least part of a first sidewall of the second gate trench section 180-2.

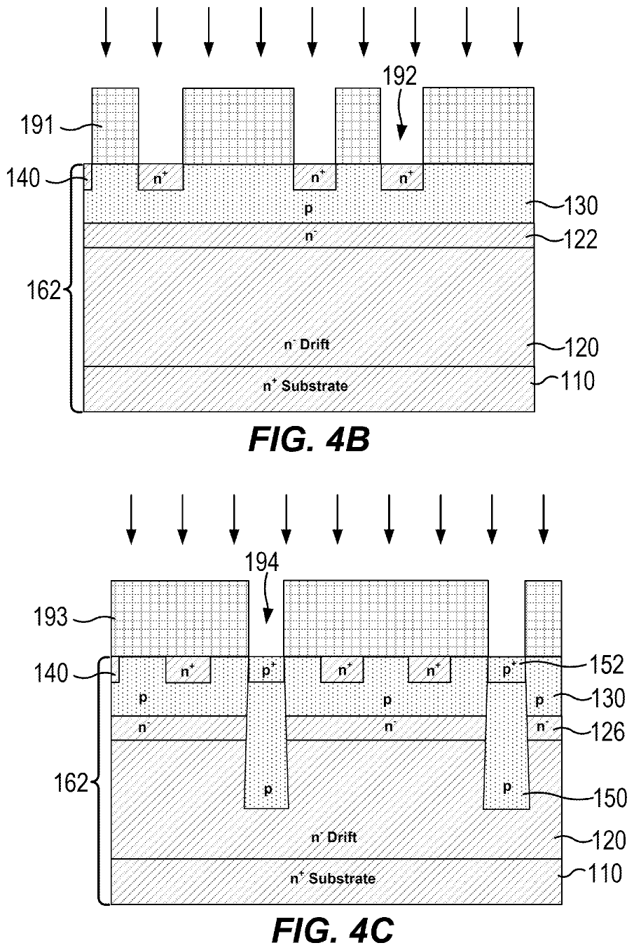

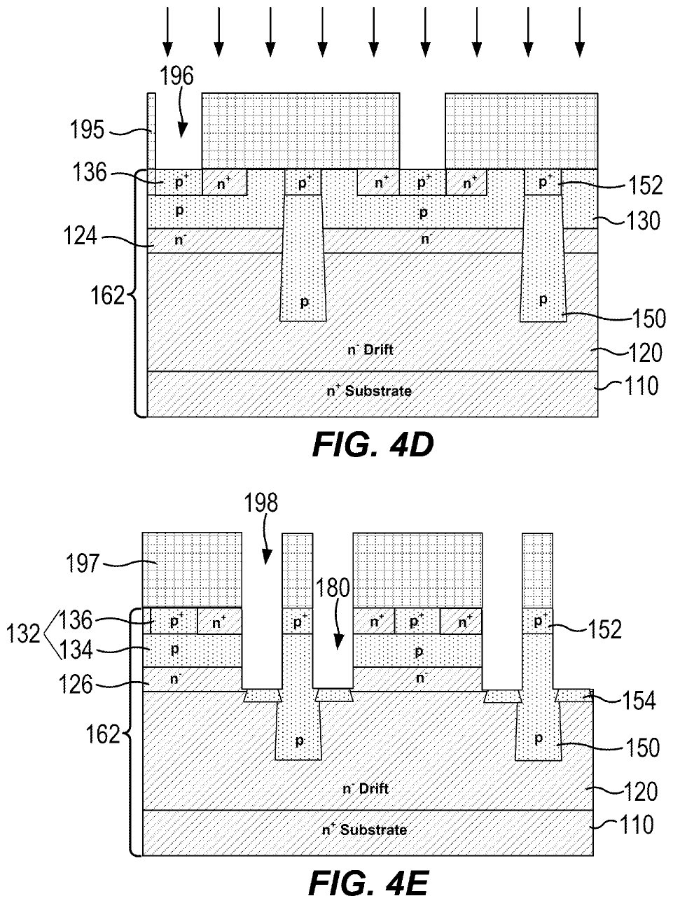

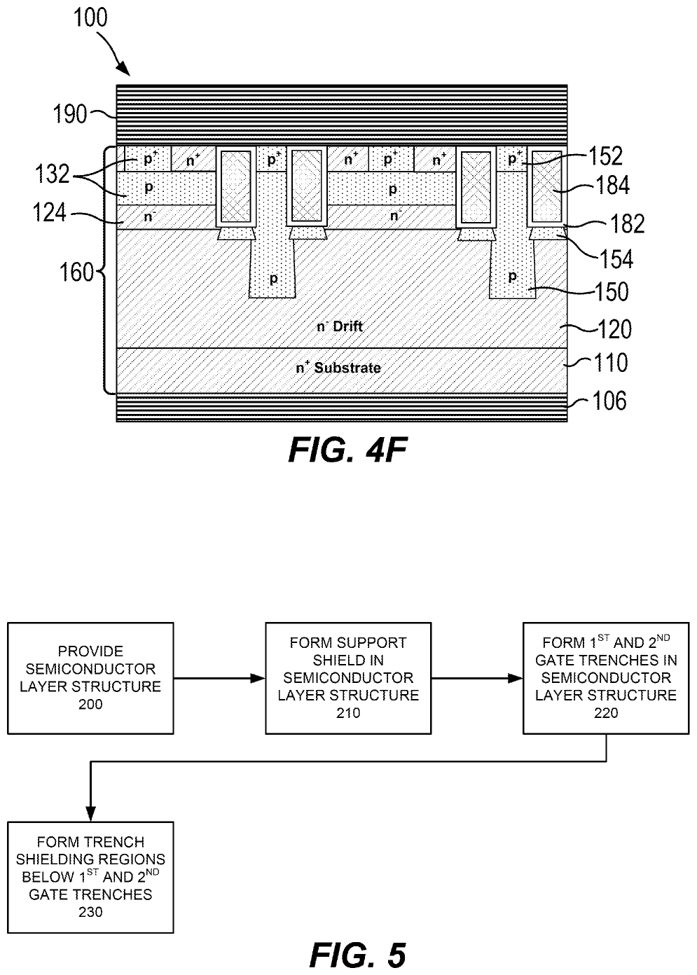

FIGS. 4A-4F are schematic cross-sectional views illustrating a method of fabricating the gate trench silicon carbide power MOSFET 100 of FIGS. 3A-3D.

Referring to FIG. 4A, the n-type silicon carbide substrate 110 is provided. The lightly-doped (n) silicon carbide drift layer 120 is then formed on an upper surface of the substrate 110, typically via epitaxial growth. The n-type dopant concentration may be increased during the growth of the upper portion of the drift layer 120 to form a JFET layer 122 in the upper portion of the drift layer 120. The epitaxial growth process may then continue (with the n-type dopant source left turned on or turned off) to grow a layer 124 on the upper surface of the JFET layer 122. The layer 124 will be converted into, among other things, the p-type well regions 132 and the n-type source regions 140 in later processing steps. The substrate 110, the drift layer 120, the JFET layer 122 and the layer 124 form a preliminary semiconductor layer structure 162.

Referring to FIG. 4B, p-type dopants may be implanted into the upper surface of the preliminary semiconductor layer structure 162 to convert all or a lower part of the layer 124 into a p-well layer 130. The p-well layer 130 may have a p-type doping concentration that matches a desired p-type doping concentration for the moderately doped lower portions 134 of the p-wells 132. Next, a first mask layer such as, for example, an oxide mask layer is formed on the upper surface of the preliminary semiconductor layer structure 162. The first mask layer is then patterned to form openings 192 therein to provide a first patterned mask 191 that exposes selected portions of the preliminary semiconductor layer structure 162. The openings 192 may be centered above locations in the preliminary semiconductor layer structure 162 in which the source regions 140 will be formed. A low energy, high dosage ion implantation process is then performed to implant n-type dopant ions into the preliminary semiconductor layer structure 162 to form the heavily doped n-type source regions 140. The first patterned mask 191 may then be removed.

Referring to FIG. 4C, a second mask layer is formed on the upper surface of the preliminary semiconductor layer structure 162 and patterned to form a second patterned mask 193. A second ion implantation process is performed to implant p-type ions into the upper portion of the preliminary semiconductor layer structure 162. The second ion implantation process may include a high energy, moderate dosage implantation step that is used to form the buried support shields 150 and a lower energy, high dosage implantation step that is used to form the support shield contact regions 152.

Referring to FIG. 4D, a third patterned mask 195 may be formed that has openings 196 that expose portions of the preliminary semiconductor layer structure 162 where the well contact regions 136 will be formed. Next, a lower energy, high dosage ion implantation process is formed to implant p-type dopants into the preliminary semiconductor layer structure 162 to form the well contact regions 136. The third patterned mask 195 may then be removed.

Referring to FIG. 4E, a fourth mask layer is formed on the preliminary semiconductor layer structure 162. The fourth mask layer may then be patterned (e.g., using standard photolithography patterning techniques) to form a fourth patterned mask 197 that has openings 198 therein that expose selected portions of the preliminary semiconductor layer structure 162. Still referring to FIG. 4E, next, an etching process is performed to form the gate trenches 180 in the preliminary semiconductor layer structure 162. The formation of the gate trenches 180 converts the well layer 130 into regions 134 so that a plurality of p-wells 132 are defined, where each p-well includes a lower portion 134 and a well contact region 136 that is above the lower portion 134. As shown, in some embodiments the gate trenches 180 may not extend as deep into the preliminary semiconductor layer structure 162 as the bottoms of the support shields 150. Next, an ion implantation process is performed using the fourth patterned mask as an implant mask to implant p-type dopant ions into the portions of the preliminary semiconductor layer structure 162 that are underneath the gate trenches 180 to form the trench shielding patterns 154, thereby converting the preliminary semiconductor layer structure 162 into the semiconductor layer structure 160. As discussed above, the trench shielding patterns 154 may not extend as deeply into the semiconductor layer structure 160 as the support shields 150 in some embodiments. The trench shielding patterns 154 underneath the gate trenches 180 that form each pair of gate trenches 180P may merge into their respective associated support shields 150 that are interposed between the gate trenches 180 of each pair of gate trenches 180P, so that the support shields 150 electrically connect the trench shielding patterns 154 to the source metallization layer 190. The fourth patterned mask 197 may then be removed.

Referring to FIG. 4F, the gate oxide layers 182 and gate electrodes 184 may then be formed in the gate trenches 180, and the intermetal dielectric layers 188 are formed to cover the gate oxide layers 182 and gate electrodes 184. The source metallization layer 190 is then formed on the source regions 140, the intermetal dielectric layers 188, the support shield contact regions 136 and the support shield contact regions 152. The drain pad 106 is then formed on the bottom of the substrate 110

FIG. 5 is a flow chart illustrating a method of forming the gate trench silicon carbide power MOSFET of FIGS. 3A-3D. As shown in FIG. 5, first a silicon carbide based semiconductor layer structure 160 is provided (Block 200). The semiconductor layer structure 160 includes a drift layer 120 having a first conductivity type.

Next, second conductivity type dopants are implanted into the semiconductor layer structure 160 to form a support shield 150 in the semiconductor layer structure 160 (Block 210). Then first and second gate trenches 180 are formed in the semiconductor layer structure 160 by, for example, forming an etch mask on the upper surface of the semiconductor layer structure 160, patterning the etch mask to expose selected regions of the semiconductor layer structure 160 where the gate trenches 180 will be formed, and then etching the exposed portions of the semiconductor layer structure 160 to form the first and second gate trenches 180 in the semiconductor layer structure 160 (Block 220).

Next, an ion implantation mask layer is formed on the upper surface of the semiconductor layer structure 160 and is patterned to provide a patterned mask having openings therein. The ion implantation mask is then used to implant second conductivity type dopants into a first portion of the semiconductor layer structure 160 that forms a bottom of the first gate trench 180-1 and into a second portion of the semiconductor layer structure 160 that forms a bottom of the second gate trench 180-2 to form a first trench shielding region 154 below the first gate trench 180-1 and a second trench shielding region 154 below the second gate trench 180-2 (Block 230).

In some embodiments, the support shield 150 may merge into the first and second trench shielding regions 154. In some embodiments, a first maximum depth into the semiconductor layer structure 160 of the support shield 150 is greater than a second maximum depth into the semiconductor layer structure 160 of the first trench shielding region 154.

It will be appreciated that the processing steps discussed above with reference to FIGS. 4A-4F and 5 could be performed in different orders in further embodiments. It will also be appreciated that some of the processing steps could be omitted in other embodiments, and/or that other processing steps may be added to the method.

FIGS. 6A-6C are schematic cross-sectional views of gate trench silicon carbide power MOSFETs 100A-100C, respectively, that are modified versions of the gate trench silicon carbide power MOSFET 100. Gate trench silicon carbide power MOSFETs 100A-100C are similar to MOSFET 100, so the discussion below will focus solely on the difference between each of MOSFETs 100A-100C and MOSFET 100.

As can be seen by comparing FIG. 3D and FIG. 6A, MOSFET 100A differs from MOSFET 100 in that MOSFET 100A includes p-type trench shielding regions 154A that extend deeper into the semiconductor layer structure 160 than the p-type support shields 150A. In the embodiment of FIG. 6A, the trench shielding regions 154A serve as the primary structure for reducing the electric fields in the gate oxide layers 182 during reverse blocking operation and the support shields 150A may primarily act to electrically connect the trench shielding regions 154A to the source metallization layer 190. Otherwise, MOSFET 100A may be identical to MOSFET 100, so further description thereof will be omitted.

Referring to FIG. 6B, a MOSFET 100B is depicted that is similar to MOSFET 100 of FIGS. 3A-3D, but the trench shielding regions 154B included in MOSFET 100B are wider than the trench shielding regions 154 in MOSFET 100 so that the trench shielding regions 154B extend laterally beyond the outer sidewalls of the gate trenches 180 in each pair of gate trenches 180P and may cover the lowermost portion each outer sidewall of the gate trenches 180, as shown. Extending the lateral width of each trench shielding region 154B so the trench shielding regions 154B extend laterally beyond the outer sidewalls of the gate trenches 180 provides increased protection to the most vulnerable portion of the gate dielectric layers 182, namely the portion of each gate dielectric layer 182 that is formed in the outer bottom corner of each gate trench 180. The increased protection of the gate oxide layer 182 may, however, come at the cost of an increase in the on-state resistance of MOSFET 100B as compared to MOSFET 100. Angled ion implants or other techniques may be used to extend the lateral widths of the trench shielding regions 154B.

Referring to FIG. 6C, a MOSFET 100C is depicted that is similar to MOSFET 100A of FIG. 6A, but the trench shielding regions 154C included in MOSFET 100C are wider than the trench shielding regions 154A in MOSFET 100A so that the trench shielding regions 154C extend laterally beyond the outer sidewalls of the gate trenches 180 in each pair of gate trenches 180P and may cover the lowermost portion each outer sidewall of the gate trenches 180, as shown. As with MOSFET 100B, this design provides increased protection from high electric field values during reverse blocking operation to the portion of each gate dielectric layer 182 that is formed in the outer bottom corner of each gate trench 180.

It will also be appreciated that the support shields (e.g., the support shields 150 of MOSFET 100) need not form the inner sidewalls of the gate trenches 180. For example, FIG. 7 is a schematic cross-sectional view of a MOSFET 300 according to further embodiments of the present invention. As can be seen, at least the upper portion of each support shield 350 has a width that is less than a lateral distance between the gate trenches 180 of each pair of gate trenches 180P. As a result, small portions of the JFET layer 126 may be positioned between each support shield 350 and its associated gate trenches 180. In some embodiments, the trench shielding regions 354 may be formed to extend to a sufficient depth into the semiconductor layer structure 360 so that the support shield 350 merges into the inner sidewalls of the trench shielding regions 354 to electrically connect the trench shielding regions 354 to the source metallization layer 190. In other words, even though upper portions of the support shields 350 may have a lateral width that is less than the lateral distance between the gate trenches 180 of each pair of gate trenches 180P, the lower portions of the support shields 350 may merge into their associated trench shielding regions 354 to electrically connect the trench shielding regions 354 to the source metallization layer 190. The “blooming” of the trench shielding regions 354 and the support shields 350 allow for this to occur.

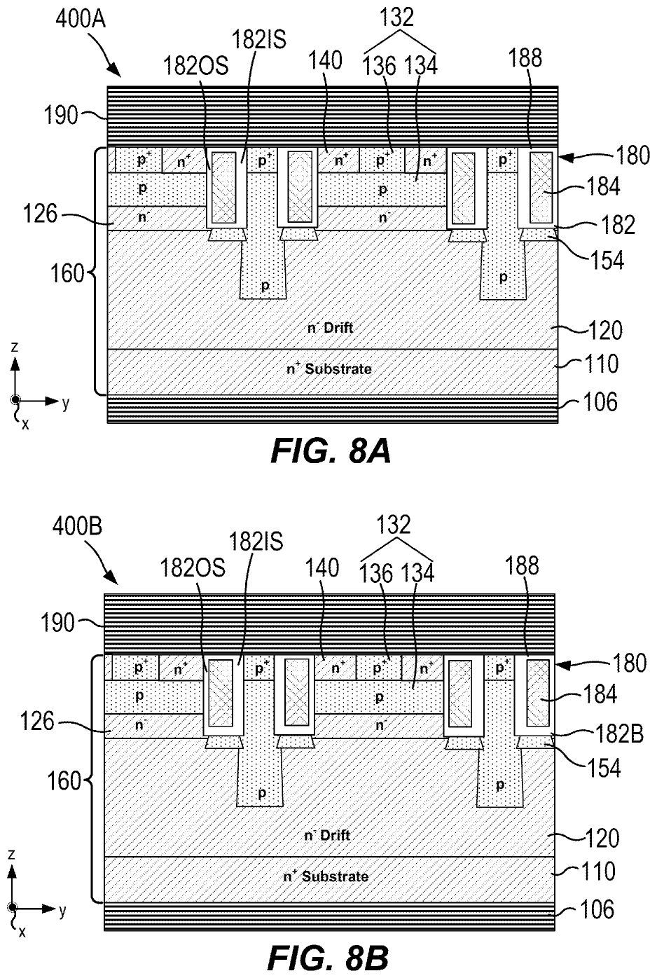

FIGS. 8A-8B are schematic cross-sectional views of gate trench silicon carbide power MOSFETs 400A and 400B according to still further embodiments of the present invention. As can be seen by comparing FIG. 3D and FIG. 8A, the only difference between MOSFET 100 and MOSFET 400A is that the portion 182IS of each gate dielectric layer 182 that is formed on the inner sidewall of each gate trench 180 in a pair of gate trenches 180P is thicker than the portion 1820S of each gate dielectric layer 182 that is formed on the outer sidewall of each gate trench 180 in a pair of gate trenches 180P. The thicker inner portion 182IS of each gate dielectric layer 182 will be less susceptible to breakdown as a longer percolation path must form for breakdown to occur. The inner portion 182IS of each gate dielectric layer 182 may be made thicker because a channel region is not provided in the inner sidewall of each gate trench 180, and thus the thickness of the gate dielectric layer 182 on the inner sidewall of each gate trench is not constrained by device performance characteristics. In some embodiments, the inner portion 182IS of each gate dielectric layer 182 may be 1.25 times, 3 times, 5 times, 10 times, 20 times, 40 times, 60 times, 80 times or 100 times the thickness of the outer portion of each gate oxide layer 182.

As can be seen by comparing FIG. 8A and FIG. 8B, the only difference between MOSFET 400A and MOSFET 400B is that the portion 182B of each gate dielectric layer 182 that is formed on the bottom of each gate trench 180 is thicker than the portion 1820S of each gate dielectric layer 182 that is formed on the outer sidewall of each gate trench 180. The thicker bottom portion 182B of each gate dielectric layer 182 will be less susceptible to breakdown as a longer percolation path must form for breakdown to occur. The bottom portion 182B of each gate dielectric layer 182 may be made thicker because a channel region is not provided in the bottom of each gate trench 180, and thus the thickness of the gate dielectric layer 182 on the bottom of each gate trench 180 is not constrained by device performance characteristics. In some embodiments, the bottom portion 182B of each gate dielectric layer 182 may be 1.25 times, 3 times, 5 times, 10 times, 20 times, 40 times, 60 times, 80 times or 100 times the thickness of the outer portion 1820S of each gate dielectric layer 182. While not shown in the drawings, in other embodiments only the bottom portion 182B of the gate dielectric layer 182 in each gate trench 180 may be made thicker than the portion 1820S of the gate dielectric layer 182 on the outer sidewall of each gate trench 180 (i.e., in such embodiments, the portions of the gate dielectric layer 182 on the inner and outer sidewalls of the gate trenches 180 may have the same thickness).

Thus, as shown in FIGS. 8A-8B, in some embodiments, a lateral thickness of a first portion 182IS of the first gate dielectric layer 182 that is on a first sidewall of the first gate trench section 180-1 that faces the second gate trench section 180-2 is greater than a lateral thickness of a second portion 1820S of the first gate dielectric layer 182 that is on a second sidewall of the first gate trench section 180-1, and a lateral thickness of a first portion 182IS of the second gate dielectric layer 182 that is on a first sidewall of the second gate trench section 180-2 that faces the first gate trench section 180-1 is greater than a lateral thickness of a second portion 1820S of the second gate dielectric layer 182 that is on a second sidewall of the second gate trench section 180-2. In some embodiments, a thickness of a bottom portion 182B of the first gate dielectric layer 182 may be greater than a thickness of the first portion 1820S of the first gate dielectric layer 182, and a thickness of a bottom portion 182B of the second gate dielectric layer 182 is greater than a thickness of the first portion 1820S of the second gate dielectric layer 182.

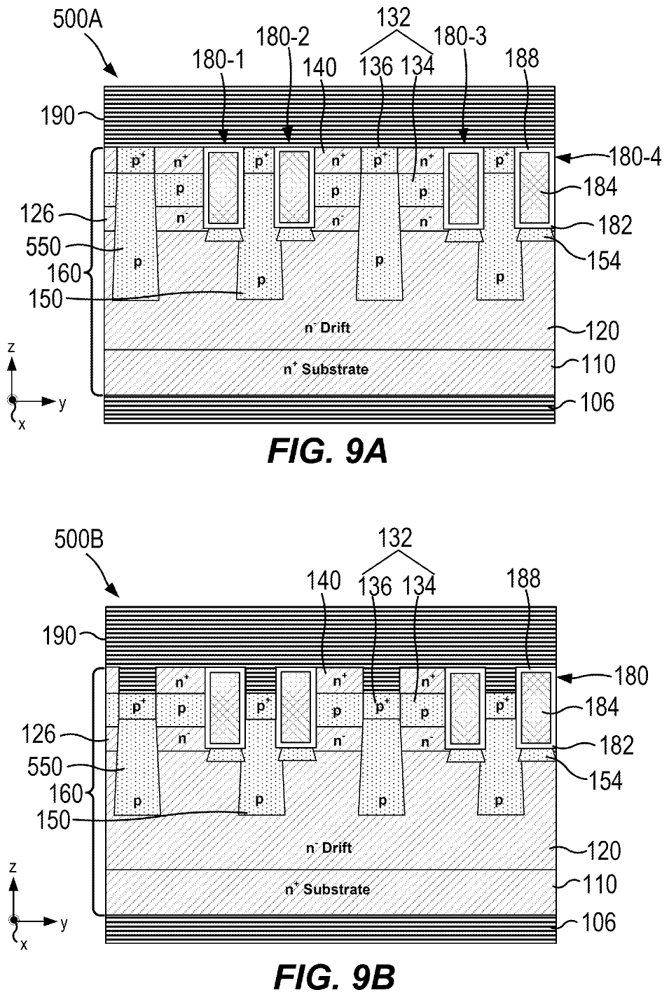

FIGS. 9A and 9B are schematic cross-sectional views of gate trench silicon carbide power MOSFETs 500A, 500B, respectively, according to still further embodiments of the present invention. The gate trench silicon carbide power MOSFETs 500A, 500B may be identical to the gate trench silicon carbide power MOSFET 100 when viewed in plan view, and hence FIG. 3A also accurately represents power MOSFETs 500A, 500B. As most of the elements of power MOSFETs 500A, 500B are the same as the corresponding elements of power MOSFET 100, the same reference numerals are used for those elements in FIGS. 3D and FIGS. 9A-9B. The description below will focus on the elements of power MOSFETs 500A, 500B that differ from power MOSFET 100.

As can be seen by comparing FIGS. 3D and 9A, power MOSFET 500A may be identical to power MOSFET 100 except that power MOSFET 500A further includes additional support shields 550 that are provided in between adjacent pairs of gate trenches 180P. The additional support shields 550 may help further protect the gate dielectric layers 182 during reverse bias operation and, more particularly, the portions 1820S of the gate dielectric layers 182 that are on the outer sidewalls of each gate trench 180 in a pair of gate trenches 180P. Thus, as shown in FIG. 9A, in some embodiments, the MOSFETs may further comprise a third gate trench 180-3 that extends into the semiconductor layer structure 160, where the first and third gate trenches 180-1, 180-3 are the closest gate trenches to the second gate trench 180-2. A second support shield 550 having the second conductivity type may be provided in the semiconductor layer structure 160 so that a first support shield 150 is provided between the first and second gate trenches 180-1, 180-2 and the second support shield 550 is provided in between the second gate trench 180-2 and the third gate trench 180-3. A minimum distance between the second gate trench 180-2 and the second support shield 550 may be greater than a minimum distance between the second gate trench 180-2 and the first support shield 150.

As can be seen by comparing FIGS. 9A and 9B, power MOSFET 500B may be identical to power MOSFET 500A except that in power MOSFET 500B the upper portion of the semiconductor layer structure 160 that is above each support shield 150, 550 is recessed to, for example, the depth of the source regions, and the source metallization layer 190 is formed in these recesses. This allows the source metallization layer 190 to contact both the upper surface and a side surface of each source region 140, which may advantageously lower the resistance of the connection between the source metallization layer 190 and the source regions 140. The support shields 150, 550 may be formed by implanting ions through the lower surfaces of the above-discussed recesses, which allows for deeper and/or lower energy implants, both of which may be advantageous.

FIGS. 10A, 11A and 12A are schematic top view of gate trench silicon carbide power MOSFETs 600, 700, 800, respectively, according to still additional embodiments of the present invention with various of the upper metal and dielectric layers removed. FIGS. 10B, 11B and 12B are schematic cross-sectional views of the gate trench silicon carbide power MOSFET 600, 700, 800 of FIGS. 10A, 11A and 12A that are taken along lines 10B-10B, 11B-11B, and 12B-12B, respectively, of FIGS. 10A, 11A and 12A. FIGS. 10A-12B illustrate how the techniques described above may also be applied to MOSFETs having a unit cell configuration.

Conventionally, most power MOSFETs have a “stripe” configuration in which the well regions, gate fingers, source regions, etc. are formed as longitudinally-extending stripes on/in the semiconductor layer structure. More recently, power MOSFETs have been proposed that have source regions or the well contact regions are formed as spaced-apart islands when the semiconductor layer structure is viewed from above. These power MOSFETs are referred to as having a “cell configuration.” MOSFETs having cell configurations may provide higher cell (or MOS channel) packing density than MOSFETs having the more conventional stripe configuration.

FIG. 10A is a horizontal cross-sectional view of a MOSFET 600 that has a cell configuration in which the well contact regions appear as circular islands when viewed from above. FIG. 10B is a vertical cross-sectional view taken along line 10B-10B of FIG. 10A. The view of FIG. 10A is taken along line 10A of FIG. 10B.

As shown in FIGS. 10A-10B, the source region 640 comprises a continuous region when viewed from above. A continuous p-well 632 is provided underneath the source region 640, and well contact regions 636 portions of the p-wells extend upwardly through the source region 640. A plurality of annular gate trenches 680 are formed in the upper surface of the semiconductor layer structure 660, and gate dielectric layers 682, gate electrodes 684 and intermetal dielectric layers 688 are formed in the gate trenches 680. A support shield contact region 652 is formed in the semiconductor layer structure 660 in the region defined within each annular gate trench 680, and a support shield 650 is formed underneath each support shield contact region 652. Trench shielding regions 654 are formed underneath each annular gate trench 680.

The MOSFET 600 is the cell configuration equivalent of the stripe MOSFET 100 of FIGS. 3A-3D. As can be seen by comparing FIGS. 3D and 10B, in cross-section the two MOSFETs 100, 600 may appear to be identical, except that each pair of gate trenches 180 and trench shielding regions 154 of MOSFET 100 are replaced with a single annular gate trench/trench shielding region 680/654 in MOSFET 600. As the structure and operation of MOSFETs 100 and 600 are otherwise the same further description of MOSFET 600 will be omitted.

FIG. 11A is a horizontal cross-sectional view of a MOSFET 700 that has a cell configuration in which the well contact regions appear as circular islands when viewed from above. FIG. 11B is a vertical cross-sectional view taken along line 11B-11B of FIG. 11A. The view of FIG. 11A is taken along line 11A of FIG. 11B.

As shown in FIGS. 11A-11B, the MOSFET 700 is similar to MOSFET 600, except that in MOSFET 700 the source regions 740 appear as a plurality of islands and the support shield contact region 752 comprises a continuous region when viewed from above. Once again, a plurality of annular gate trenches 780 are formed in the upper surface of the semiconductor layer structure 760, and gate dielectric layers 782 and gate electrodes 784 are formed in the gate trenches 780. The source regions 740 are formed in the semiconductor layer structure 760 in the region defined within each annular gate trench 780. One or more support shields 750 are formed underneath the support shield contact region 752. Trench shielding regions 754 are formed underneath each annular gate trench 780. The MOSFET 700 is simply a different cell configuration design than MOSFET 600. Thus, MOSFET 700 shows that the techniques disclosed herein are applicable to any cell configuration MOSFET design.

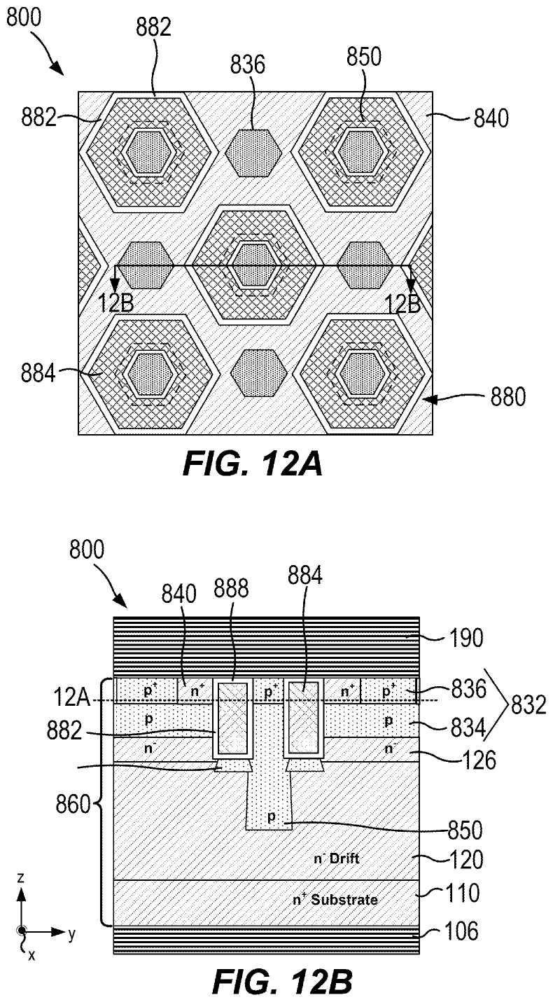

FIG. 12A is a horizontal cross-sectional view of a MOSFET 800 that has a cell configuration in which the well contact regions appear as circular islands when viewed from above. FIG. 12B is a vertical cross-sectional view taken along line 12B-12B of FIG. 12A. The view of FIG. 12A is taken along line 12A of FIG. 12B.

As shown in FIGS. 12A-12B, the MOSFET 800 is similar to MOSFET 600, except that in MOSFET 800 the well contact regions 836, the support shields 850 and the support shield contact regions 852 have hexagonal shapes, and the gate trenches 880, gate dielectric layers 882 and gate electrodes 884 have annular hexagonal shapes. Otherwise, MOSFET 800 may be substantially identical to MOSFET 600, and hence further description thereof will be omitted here. MOSFET 800 shows that the techniques disclosed herein are applicable to cell configuration MOSFET designs having any trench gate shape.

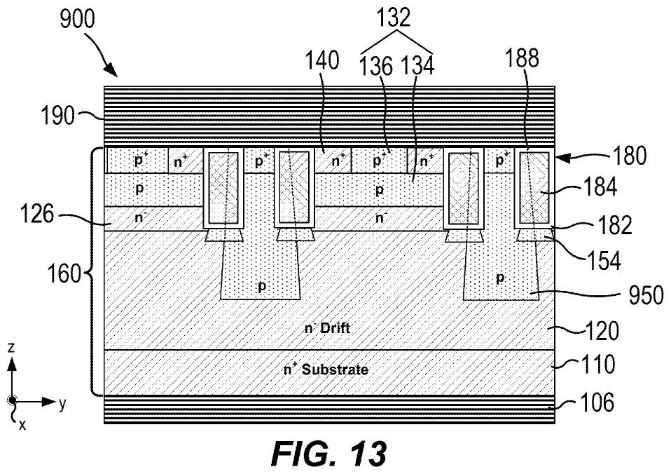

FIG. 13 is a schematic cross-sectional view of a power MOSFET 900 according to further embodiments of the present invention that has widened support shields. The power MOSFET 900 is almost identical to power MOSFET 100 of FIGS. 3A-3D, except that the support shields 950 in power MOSFET 900 are made much wider than the corresponding support shields 150 in power MOSFET 100. As shown by the dashed lines in FIG. 13, the ion implantation step used to form the support shields 950 may implant ions into portions of the semiconductor layer structure that are ultimately etched away during the formation of the gate trenches 180. In other words, as originally formed, the uppermost portion of each support shield 950 is wider than the lateral distance in between the two gate trenches 180 in each pair of gate trenches 180P. Since the support shields 950 are widened, the bottom portions of the support shields 950 extend farther underneath each gate trench 180, and hence may provide enhanced protection to the lower outer corners of the gate dielectric layers 182 during reverse bias operation. The widened support shields also exhibit greater overlap with the trench shielding regions 154, and hence may provide lower resistance electrical connections between the trench shielding regions 154 and the supports shields 950 as compared to the similar connections in power MOSFET 100.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10%.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a silicon carbide based semiconductor layer structure that comprises a drift region having a first conductivity type and an implanted region having a second conductivity type on the drift region;
a first gate trench section in the semiconductor layer structure; and
a second gate trench section in the semiconductor layer structure;
wherein a first maximum depth into the semiconductor layer structure of a first portion of the implanted region that is between the first gate trench section and the second gate trench section is different than a second maximum depth into the semiconductor layer structure of a second portion of the implanted region that extends downwardly underneath the first gate trench section.

2. The semiconductor device of claim 1, wherein the first maximum depth is greater than the second maximum depth.

3. The semiconductor device of claim 2, wherein the implanted region comprises a first trench shielding region that is below the first gate trench section, a second trench shielding region that is below the second gate trench section and a support shield that is at least partially in between the first gate trench section and the second gate trench section.

4. The semiconductor device of claim 3, wherein the semiconductor layer structure further comprises a well region having the second conductivity type on the drift region, an upper portion of the drift region comprises a JFET region that has a higher concentration of first conductivity type dopants than a lower portion of the drift region, and the support shield extends downwardly through the JFET region into the lower portion of the drift region, wherein the first trench shielding region and the second trench shielding region do not extend through the JFET region into the lower portion of the drift region.

5-8. (canceled)

9. The semiconductor device of claim 1, further comprising a first gate dielectric layer in the first gate trench section and a second gate dielectric layer in the second gate trench section,
wherein a lateral thickness of a first portion of the first gate dielectric layer that is on a first sidewall of the first gate trench section that faces the second gate trench section is greater than a lateral thickness of a second portion of the first gate dielectric layer that is on a second sidewall of the first gate trench section, and
wherein a lateral thickness of a first portion of the second gate dielectric layer that is on a first sidewall of the second gate trench section that faces the first gate trench section is greater than a lateral thickness of a second portion of the second gate dielectric layer that is on a second sidewall of the second gate trench section.

10. (canceled)

11. The semiconductor device of claim 1, wherein the first gate trench section is part of a first gate trench, the second gate trench section is part of a second gate trench, where the second gate trench is spaced apart from the first gate trench and extends in parallel to the first gate trench.

12. The semiconductor device of claim 11, further comprising:
a third gate trench extending into the semiconductor layer structure, where the first and third gate trenches are the closest gate trenches to the second gate trench,
wherein the support shield is a first support shield and the semiconductor layer structure further comprises a second support shield having the second conductivity type in between the second gate trench and the third gate trench.

13. The semiconductor device of claim 12, wherein a minimum distance between the second gate trench and the second support shield is greater than a minimum distance between the second gate trench and the first support shield.

14. The semiconductor device of claim 1, wherein the first gate trench section and the second gate trench section are both part of a first gate trench.

15. The semiconductor device of claim 14, wherein the first gate trench has a closed ring shape when viewed from above.

16. The semiconductor device of claim 1, wherein the first maximum depth is less than the second maximum depth.

17. (canceled)

18. A semiconductor device, comprising:
a silicon carbide based semiconductor layer structure that comprises a drift region having a first conductivity type, a first trench shielding region having a second conductivity type in the drift region, a second trench shielding region having the second conductivity type in the drift region, and a support shield having the second conductivity type;
a first gate trench section in the semiconductor layer structure; and
a second gate trench section in the semiconductor layer structure;
wherein the support shield vertically overlaps both the first gate trench section and the second gate trench section, and a maximum depth of the support shield into the semiconductor layer structure differs from a maximum depth of the first trench shielding region into the semiconductor layer structure.

19. The semiconductor device of claim 18, wherein the maximum depth of the support shield into the semiconductor layer structure is greater than the maximum depth of the first trench shielding region into the semiconductor layer structure.

20-25. (canceled)

26. The semiconductor device of claim 18, wherein the first gate trench section is part of a first gate trench, the second gate trench section is part of a second gate trench, where the second gate trench is spaced apparat from the first gate trench and extends in parallel to the first gate trench.

27. The semiconductor device of claim 26, further comprising:
a third gate trench extending into the semiconductor layer structure, where the first and third gate trenches are the closest gate trenches to the second gate trench,
wherein the support shield comprises a first support shield and the semiconductor layer structure further comprises a second support shield having the second conductivity type in between the second gate trench and the third gate trench.

28. The semiconductor device of claim 27, wherein a minimum distance between the second gate trench and the second support shield is greater than a minimum distance between the second gate trench and the first support shield.

29. The semiconductor device of claim 18, further comprising a first gate dielectric layer in the first gate trench section and a second gate dielectric layer in the second gate trench section,
wherein a lateral thickness of a first portion of the first gate dielectric layer that is on a first sidewall of the first gate trench section that faces the second gate trench section is greater than a lateral thickness of a second portion of the first gate dielectric layer that is on a second sidewall of the first gate trench section, and
wherein a lateral thickness of a first portion of the second gate dielectric layer that is on a first sidewall of the second gate trench section that faces the first gate trench section is greater than a lateral thickness of a second portion of the second gate dielectric layer that is on a second sidewall of the second gate trench section.

30. The semiconductor device of claim 29, wherein a thickness of a bottom portion of the first gate dielectric layer is greater than a thickness of the first portion of the first gate dielectric layer, and
wherein a thickness of a bottom portion of the second gate dielectric layer is greater than a thickness of the first portion of the second gate dielectric layer.

31. The semiconductor device of claim 18, wherein the first gate trench section and the second gate trench section are both part of a first gate trench.

32-33. (canceled)

34. A semiconductor device, comprising:
a silicon carbide based semiconductor layer structure that comprises a drift region having a first conductivity type;
a first gate trench and a second gate trench in the semiconductor layer structure that form a first pair of gate trenches, where the first gate trench is adjacent the second gate trench;
a third gate trench and a fourth gate trench in the semiconductor layer structure that form a second pair of gate trenches, the second pair of gate trenches adjacent the first pair of gate trenches, where the third gate trench is adjacent the fourth gate trench;
a first support shield having the second conductivity type in the semiconductor layer structure, an upper portion of the first support shield in between the first gate trench and the second gate trench;
a second support shield having the second conductivity type in the semiconductor layer structure, an upper portion of the second support shield in between the third gate trench and the fourth gate trench; and
a third support shield having the second conductivity type in the semiconductor layer structure in between the first pair of gate trenches and the second pair of gate trenches,
wherein a distance between the third support shield and closest one of the first through fourth gate trenches exceeds a distance between the first support shield and the first gate trench.

35. The semiconductor device of claim 34, wherein the semiconductor layer structure further comprises a first trench shielding region having a second conductivity type underneath the first gate trench and a second trench shielding region having the second conductivity type underneath the second gate trench, and the first support shield merges into the first and second trench shielding regions.

36. The semiconductor device of claim 35, wherein a maximum depth of the first support shield exceeds a maximum depth of the first trench shielding region.

37. (canceled)

38. The semiconductor device of claim 34, wherein the first support shield forms a first sidewall of the first gate trench and a first sidewall of the second gate trench.

39-48. (canceled)
